(19) United States
(12) Patent Application Publication
(10) Pub. No.: US 2010/0053043 A1
(43) Pub. Date: Mar. 4, 2010

(54) COLOR DISPLAY AND METHOD FOR PRODUCING THE SAME

(75) Inventor: Yoshiaki SAKAMOTO, Kanagawa (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/506,274

(22) Filed: Jul. 21, 2009

(30) Foreign Application Priority Data
Aug. 29, 2008 (JP) 2008-221879
Mar. 19, 2009 (JP) 2009-067723

(51) Int. Cl. G09G 3/30

(52) U.S. Cl. 345/77

(57) ABSTRACT

A color display using an organic electroluminescence element, includes, on a substrate, plural pixels each being area-divided into plural sub-pixels including at least two sub-pixels that each emit colored light of different wavelengths and a white sub-pixel, in which the white sub-pixel is further area-divided into at least two sub-sub-pixels that each emit colored light of different wavelengths, wherein the at least two sub-pixels and the at least two sub-sub-pixels each have an organic electroluminescence layer that emits a white light and a color filter. A color display which allows a high definition color display and is easily produced, and a method for producing the color display are provided.

### CROSS-REFERENCE TO RELATED APPLICATION

This application claims priority under 35 USC 119 from Japanese Patent Application Nos. 2008-221879 filed on Aug. 29, 2008, and 2009-67723 filed on Mar. 19, 2009, the disclosures of which are incorporated by reference herein.

### BACKGROUND OF THE INVENTION

1. Field of the Invention

The present invention relates to a color display using a light-emitting element and a method for producing the same. In particular, the invention relates to a color display that allows a high definition color display and is easily produced, and a method for producing the same.

2. Description of the Related Art

Recently, flat panel displays with a thin shape and light weight have been used in broad fields in place of Braun tubes (CRTs), and applications thereof have been expanded. This has resulted from the accelerated spread of personal information terminals such as personal computers and cellular telephones compatible with network access, due to the development of information devices and infrastructure for service networks having the Internet as a core. In addition, the market for flat panel displays has expanded to home use television sets, which was conventionally the exclusive market of CRTs.

Among these, a device recently receiving a lot of attention in particular is an organic electroluminescence element (hereinafter, referred to as an “organic EL element”, or an “organic light emitting diode” (OLED) in some cases). An organic EL element is an element that emits light corresponding to electric signals and is constituted using an organic compound as a light-emitting material. A display using the organic EL element inherently has excellent characteristics for display such as a wide viewing angle, high contrast and high-speed response. Further, there is a possibility that it can realize displays of from a small size to a large size with a thin shape and light weight and high image quality. Therefore, it has attracted attention as a display capable of replacing CRTs and LCDs.

Various full color displays using an organic EL element have been proposed.

For instance, methods for obtaining three primary colors of a red (R) color, a green (G) color, and a blue (B) color for full color representation include a triple pattern process, a color filter method of combining a color filter with a white organic EL element, a color changing method and the like.

In the triple pattern process, there is a possibility of achieving high efficiency by preparing these appropriate coloring materials as light-emitting materials and reducing loss of a circular polarizing plate. However, since the triple pattern process is technically difficult, it is hard to achieve a high definition display, and it is difficult to increase a display size.

The method of combining a color filter with a white organic EL element has problems in that the light-emission efficiency of the white light-emitting material itself is low, and that the brightness decreases to about ⅓ due to the color filter.

In the color changing method for obtaining a desired color by changing the color of a light emitted from an organic EL element using a color changing layer, various improvements have been made, but there are still problems in that a color changing efficiency to a red color is low and the like.

In contrast, it has been examined to achieve a high color reproduction by employing a translucent cathode for an upper electrode, and taking out only light of a specific wavelength to the outside of the organic EL element by a multiple interference effect between the upper electrode and a light-reflection layer. For example, the following organic EL element is known. The organic EL element is structured so that a first electrode formed of a light-reflection material, an organic layer having an organic light-emitting layer, a translucent light-reflection layer and a second electrode formed of a transparent material are successively disposed, and the organic layer serves as a resonance part, wherein the following equation is satisfied when the peak wavelength of the spectrum of a desired light to be taken out is defined as λ.

(2L)/λ+φ/(2π)=m

In the equation, L represents an optical path length, λ represents a wavelength of a desired light to be taken out, m represents an integer, and φ represents a phase shift, and the structure is designed so that the optical path length L becomes a minimum positive value.

For example, Japanese Patent Application Laid-Open (JP-A) No. 2007-265859 discloses an organic EL display which performs color display by 4 sub-pixels obtained by area-dividing one pixel into a red sub-pixel (R sub-pixel), a green sub-pixel (G sub-pixel), a blue sub-pixel (B sub-pixel), and a white sub-pixel (W sub-pixel). According to the description of JP-A No. 2007-265859, an R sub-pixel unit takes out a red light by disposing a red color filter (R filter) on an orange organic EL layer, a G sub-pixel unit takes out a green light by disposing a green color filter (G filter) on a laminate of a blue organic EL layer and an orange organic EL layer, a B sub-pixel unit takes out a blue light by disposing a blue color filter (B filter) on a blue organic EL layer, and a W sub-pixel unit provides a white light by taking out, using no color filter, light obtained by laminating a blue organic EL layer and an orange organic EL layer. However, such a structure has problems in that the structure is complicated and requires a large number of production processes, whereby a production yield decreases, and that high brightness is not obtained due to reduction in brightness by the color filters.

Japanese National Phase Publication (translation of PCT application) No. 2007-533076 discloses a display, in which a resonator resonating a specific wavelength is formed by sandwiching an organic EL layer between a translucent light reflector and a light-reflection layer, and a layer containing a color changing medium which absorbs light of a wavelength shorter than the resonant wavelength and changes the light into light of the resonant wavelength is provided. According to the structure, the color shift when observed at a position where the viewing angle is shifted from the optical axis is improved.

### SUMMARY OF THE INVENTION

The present invention has been made in view of the above circumstances and provides a color display and a method for producing the same with the following aspects.

A first aspect of the present invention provides a color display using an organic electroluminescence element, comprising, on a substrate, plural pixels each being area-divided into plural sub-pixels including at least two sub-pixels that each emit colored light of different wavelengths and a white sub-pixel, in which the white sub-pixel is further area-divided into at least two sub-sub-pixels that each emit colored light of different wavelengths, wherein the at least two sub-pixels and the at least two sub-sub-pixels each have an o organic electroluminescence layer that emits a white light and a color filter.

A second aspect of the present invention provides a method for producing a color display using an organic electroluminescence element, comprising, on a substrate, plural pixels each being area-divided into plural sub-pixels including at least two sub-pixels that each emit colored light of different wavelengths and a white sub-pixel, in which the white sub-pixel is further area-divided into at least two sub-sub-pixels that each emit colored light of different wavelengths, wherein the at least two sub-pixels and the at least two sub-sub-pixels each have an organic electroluminescence layer that emits a white light and a color filter, the method comprising:

forming the color filters for the at least two sub-pixels and the at least two sub-sub-pixels in succession with substantially the same composition for each same color; and

forming the organic electroluminescence layer that emits a white light for the at least two sub-pixels and the at least two sub-sub-pixels in succession with substantially the same composition.

### BRIEF DESCRIPTION OF THE DRAWINGS

FIG. 1 is a conceptual diagram illustrating a pixel arrangement in a multicolor display.

FIG. 2 is a conceptual diagram illustrating a sub-pixel arrangement of one pixel.

FIG. 3 is a conceptual diagram illustrating a sub-pixel arrangement of one pixel according to another embodiment.

FIG. 4 is a conceptual diagram illustrating a sub-pixel arrangement of one pixel according to yet another embodiment.

FIG. 5 is a conceptual diagram illustrating a sub-pixel arrangement of one pixel according to yet another embodiment.

FIG. 6 is a conceptual cross-sectional view of one pixel according to the invention.

FIG. 7 is a conceptual cross-sectional view of one pixel according to another embodiment of the invention.

FIG. 8 is a conceptual cross-sectional view of one pixel according to yet another embodiment of the invention.

FIG. 9 is a conceptual cross-sectional view of one pixel according to yet another embodiment of the invention.

FIG. 10 is a conceptual cross-sectional view illustrating a method for producing one pixel of the invention in accordance with a process order.

FIG. 11 is a conceptual cross-sectional view illustrating a method for producing one pixel of another embodiment of the invention in accordance with a process order.

FIG. 12 is a conceptual cross-sectional view illustrating a method for producing one pixel of yet another embodiment of the invention in accordance with a process order.

FIG. 13 is a conceptual cross-sectional view illustrating a method for producing one pixel of yet another embodiment of the invention in accordance with a process order.

FIG. 14 is a conceptual cross-sectional view of one pixel according to yet another embodiment of the invention.

FIG. 15 is a conceptual cross-sectional view illustrating a method for producing one pixel of yet another embodiment of the invention in accordance with a process order.

FIG. 16 is a conceptual cross-sectional view of one pixel according to yet another embodiment of the invention.

FIG. 17 is a conceptual cross-sectional view illustrating a method for producing one pixel of yet another embodiment of the invention in accordance with a process order.

FIG. 18 is a conceptual cross-sectional view of one pixel according to yet another embodiment of the invention.

FIG. 19 is a conceptual cross-sectional view illustrating a method for producing one pixel of yet another embodiment of the invention in accordance with a process order.

FIG. 20 is a conceptual cross-sectional view of one pixel according to yet another embodiment of the invention.

FIG. 21 is a conceptual cross-sectional view illustrating a method for producing one pixel of yet another embodiment of the invention in accordance with a process order.

FIG. 22 is a conceptual cross-sectional view of one pixel according to yet another embodiment of the invention.

FIG. 23 is a conceptual cross-sectional view illustrating a method for producing one pixel of yet another embodiment of the invention in accordance with a process order.

FIG. 24 is a conceptual cross-sectional view of one pixel according to yet another embodiment of the invention.

FIG. 25 is a conceptual cross-sectional view illustrating a method for producing one pixel of yet another embodiment of the invention in accordance with a process order.

### DETAILED DESCRIPTION OF THE INVENTION

An object of the invention is to provide a color display using a light emitting element, and a method for producing the same. In particular, the invention aims at providing a color display that allows a high definition color display and is easily produced, and a method for producing the same.

The problems of the invention described above have been solved by a color display comprising, on a substrate, plural pixels each being area-divided into plural sub-pixels including at least two sub-pixels that each emit colored light of different wavelengths and a white sub-pixel, in which the white sub-pixel is further area-divided into at least two sub-sub-pixels that each emit colored light of different wavelengths, wherein the at least two sub-pixels and the at least two sub-sub-pixels each have an organic electroluminescence layer that emits a white light and a color filter.

Preferably, the at least two sub-pixels include at least three sub-pixels including a blue sub-pixel, a green sub-pixel and a red sub-pixel, each having a blue filter, a green filter and a red filter, respectively, for each same color, and the white sub-pixel includes a blue sub-sub-pixel, a green sub-sub-pixel and a red sub-sub-pixel, each having a blue filter, a green filter and a red filter, respectively, for each same color.

Preferably, the blue filter, the green filter and the red filter of the respective blue sub-pixel, green sub-pixel and red sub-pixel, and the blue filter, the green filter and the red filter of the respective blue sub-sub-pixel, green sub-sub-pixel and red sub-sub-pixel have substantially the same composition, respectively, for each same color.

Preferably, each of the at least two sub-sub-pixels of the white sub-pixel forms a resonator.

Preferably, each of the at least two sub-pixels forms a resonator.

Preferably, each of the blue sub-pixel, the green sub-pixel and the red sub-pixel forms a resonator, and each of the blue sub-sub-pixel, the green sub-sub-pixel and the red sub-sub-pixel forms a resonator, in which the resonators of the blue sub-pixel and the blue sub-sub-pixel, the resonators of the green sub-pixel and the green sub-sub-pixel, and the resonators of the red sub-pixel and the red sub-sub-pixel have substantially the same structure, respectively, for each same color.

Another embodiment of the invention is to provide a method for producing a color display comprising, on a substrate, plural pixels each being area-divided into plural sub-pixels including at least two sub-pixels that each emit colored light of different wavelengths and a white sub-pixel, in which the white sub-pixel is further area-divided into at least two sub-sub-pixels that each emit colored light of different wavelengths, wherein the at least two sub-pixels and the at least two sub-sub-pixels each have an organic electroluminescence layer that emits a white light and a color filter, the method comprising forming the color filters for the at least two sub-pixels and the at least two sub-sub-pixels in succession with substantially the same composition for each same color, and forming the organic electroluminescence layers that emit a white light for the at least two sub-pixels and the at least two sub-sub-pixels in succession with substantially the same composition.

Preferably, in the producing method described above, the at least two sub-pixels include at least three sub-pixels including a red sub-pixel, a green sub-pixel, and a blue sub-pixel, and the white sub-pixel has a red sub-sub-pixel, a green sub-sub-pixel, and a blue sub-sub-pixel.

Preferably, in the producing method described above, the red sub-pixel, the green sub-pixel and the blue sub-pixel, and the red sub-sub-pixel, the green sub-sub-pixel and the blue sub-sub-pixel form resonators, respectively, for each same color, and optical path length-adjusting layers of the red sub-pixel and the red sub-sub-pixel, optical path length-adjusting layers of the green sub-pixel and the green sub-sub-pixel, and optical path length-adjusting layers of the blue sub-pixel and the blue sub-sub-pixel are formed to have substantially the same thickness using substantially the same material for each same color.

Preferably, in the producing method described above, the optical path length-adjusting layers are formed of an inorganic insulating material.

The invention provides a color display that allows a high definition color display and is easily produced, and a method for producing the same. In particular, the invention provides a color display that allows observation at high contrast, even when the display is located at a place where outside light enters, by preventing a reduction in contrast due to outside light-reflection with color filters of R, G, and B sub-pixels in a W sub-pixel unit, and further provides a color display that provides a white light with high brightness, because the W sub-pixel unit obtains a white light by mixing of light from sub-sub-pixels having a resonator.

In addition, according to the production method of the invention, since the organic electroluminescence layer that emits a white light can be formed uniformly in common with respect to the whole pixel including sub-pixels and sub-sub-pixels, it is not necessary to individually form organic electroluminescence layer units according to emitted colors. Moreover, with respect to the color filter, the R, G, and B filters of the sub-pixels and the R, G and B filters of the sub-sub-pixels can be provided uniformly in common respectively, or when a resonator structure is provided, an optical path length-adjusting layer for the wavelength of each of the sub-pixels and the sub-sub-pixels can be formed in common respectively. Thus, the productivity is extremely excellent, and a high definition pattern can be easily produced.

Hereinafter, the invention will be described in more detail.

### 1. Display

A display of the invention is a color display comprising, on a substrate, plural pixels each being area-divided into plural sub-pixels including at least two sub-pixels that each emit colored light of different wavelengths and a white sub-pixel, in which the white sub-pixel is further area-divided into at least two sub-sub-pixels that each emit colored light of different wavelengths, wherein the at least two sub-pixels and the at least two sub-sub-pixels each have an organic electroluminescence layer that emits a white light and a color filter.

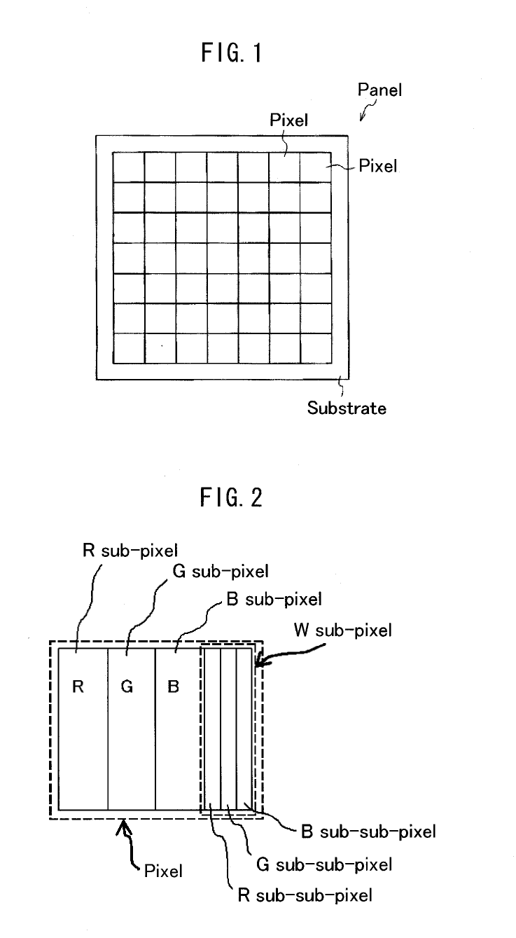

As shown in FIG. 1, the display of the invention has a matrix display panel in which plural pixels are arranged in a matrix on the substrate. Each pixel contains at least two sub-pixels which each emit colored light of different wavelengths and a white sub-pixel. Preferably, each pixel contains sub-pixels of a red (R) color, a green (G) color, a blue (B) color, and a white (W) color, and the white sub-pixel contains sub-sub-pixels of a red (R) color, a green (G) color, and a blue (B) color (FIG. 2).

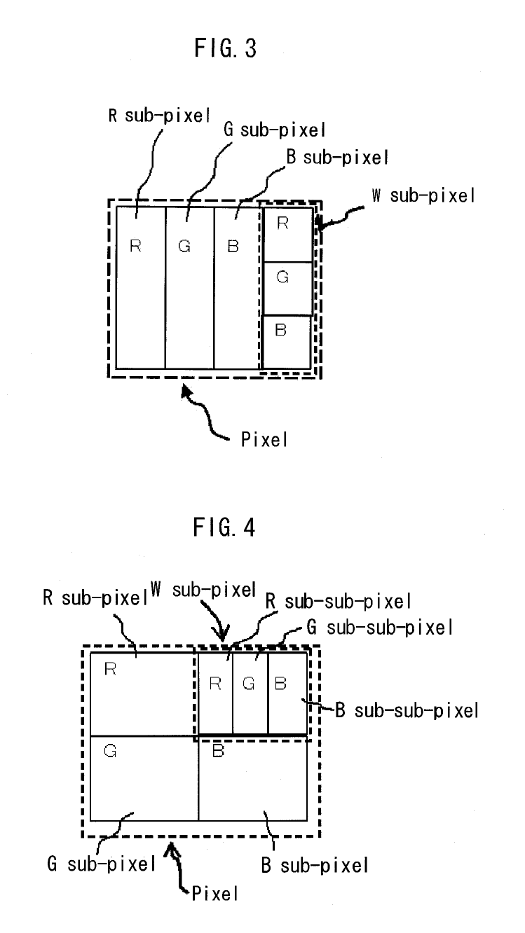

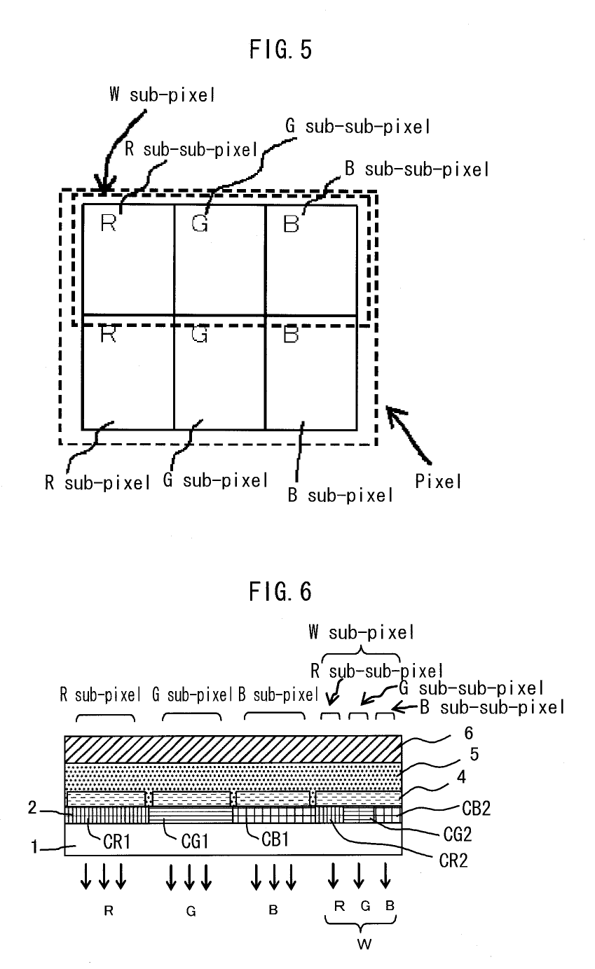

The arrangement in each pixel of the R, G, B, and W sub-pixels and the R, G, and B sub-sub-pixels is not limited to the arrangement shown in FIG. 2, and various arrangements as shown in FIGS. 3 to 5, for example, can be adopted.

The display employing the structure of the invention can be preferably used for a 2 color display or a full color display.

The R, G, and B luminescent colors of the R, G, and B sub-pixels and the R, G, and B sub-sub-pixels of each pixel in the invention are obtained by combining the color filters with a light emitted from the organic electroluminescence layer emitting a white light. Therefore, all the organic electroluminescence layers of the R, G, and B sub-pixels and the R, G, and B sub-sub-pixels can be consistently formed in common. In addition, the R, G, and B filters of the R, G, and B sub-pixels and the R, G, and B filters of the R, G, and B sub-sub-pixels can be formed of substantially the same color filter material for each same color. Furthermore, since the color filters of the W sub-pixel unit of the invention prevent outside light-reflection, high black density can be reproduced without reducing the contrast of an image to be displayed.

Next, the structure of the display of the invention will be specifically described with reference to the drawings.

FIG. 6 is a schematic configuration diagram illustrating a cross sectional view of the structure of one pixel of the invention.

On a transparent substrate 1, a color filter layer (CF layer 2) is provided corresponding to the color of each sub-pixel. An R filter (CR1), a G filter (CG1), and a B filter (CB1) are provided corresponding to the divided R, G, and B sub-pixel units, respectively. Also in the W sub-pixel, an R filter (CR2), a G filter (CG2), and a B filter (CB2) are provided corresponding to the R, G, and B sub-sub-pixel units, respectively.

On the CF layer 2, a patterned transparent electrode 4 is provided, and a white organic electroluminescence layer 5 and a light-reflection electrode 6 are provided thereon in common to each sub-pixel. Light emitted in the white organic electroluminescence layer 5 by applying an electric current transmits through the CF layer 2 of each color, and then the resulting R, G, and B lights transmit through the substrate 1 to be emitted to the outside. In the W sub-pixel, the light is observed as a white light by mixing of lights of three colors from the R, G, and B sub-sub-pixels. Since outside light-reflection is prevented by the color filters of the W sub-pixel unit, the contrast of an image displayed in a light room does not decrease, and thus reproduction of a high quality image with a clear black display region can be attained.

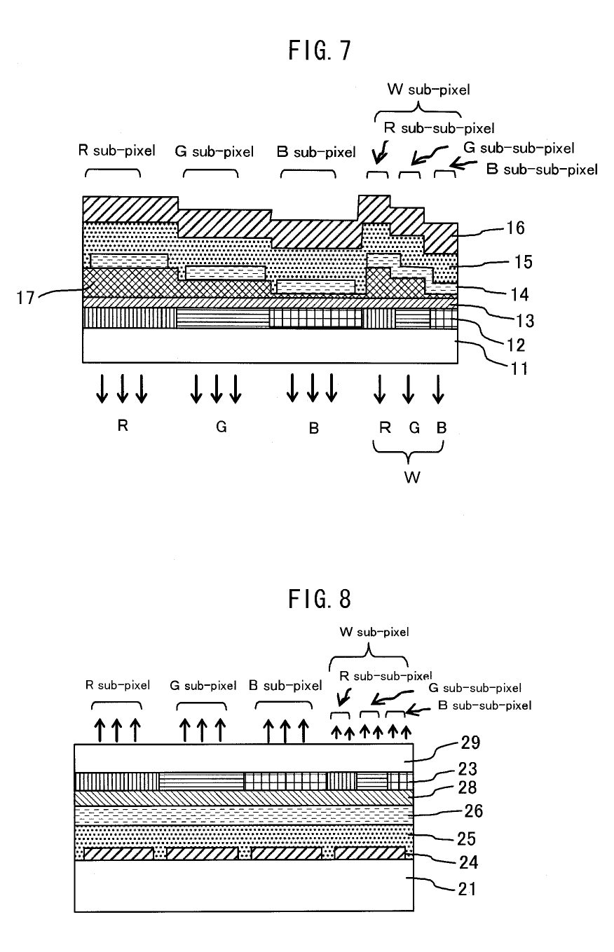

FIG. 7 is a schematic configuration diagram illustrating a cross sectional view of the structure of one pixel according to another embodiment of the invention.

On a transparent substrate 11, a color filter layer (CF layer 12) is provided corresponding to the color of each sub-pixel. An R filter (CR1), a G filter (CG1), and a B filter (CB1) are provided corresponding to the divided R, G, and B sub-pixel units, respectively. Also in the W sub-pixel, an R filter (CR2), a G filter (CG2), and a B filter (CB2) are provided corresponding to the R, G, and B sub-sub-pixel units, respectively.

On the CF layer 12, a layer that partially transmits light and partially reflects light 13 is provided in common to each sub-pixel and each sub-sub-pixel. An optical path length-adjusting layer 17 provided thereon is formed of a light transmitting material, and is disposed while changing the thickness according to the wavelength of each emitted light of the R, G, and B sub-pixel units and the R, G, and B sub-sub-pixel units. A transparent electrode 14 that is patterned according to each sub-pixel unit, is provided thereon. A white organic electroluminescence layer 15 and a light-reflection electrode 16 are provided thereon in common to each sub-pixel. The thickness of the optical path length-adjusting layer 17 is adjusted so that the distance between the light-reflection electrode 16 and the layer that partially transmits light and partially reflects light 13 becomes an optical distance in which each of the R, G, and B lights resonates.

A light emitted in the white organic EL layer 15 by applying an electric current is repeatedly reflected between the light-reflection electrode 16 and the layer that partially transmits light and partially reflects light 13, then R, G, and B lights each having a resonant wavelength transmit through the layer that partially transmits light and partially reflects light 13, and then each light transmits through the transparent substrate 11 via the R, G, or B filter to be emitted to the outside. In the W sub-pixel unit, the light is observed as a white light by mixing of the R, G, and B lights.

According to the structure of the embodiment, since the color filters of the W sub-pixel unit prevent outside light-reflection, the contrast of an image displayed in a light room does not decrease, which allows reproduction of a high quality image with a clear black display region. In addition, although the brightness decreases due to absorption of unnecessary wavelengths by the R, G, and B filters, the intensity of a required wavelength is amplified by the resonator, and thus a high brightness light can be taken out.

FIG. 8 is a schematic configuration diagram illustrating a cross sectional view of another structure of one pixel according to the invention.

On a substrate 21, a patterned light-reflection electrode 24 is provided, and a white organic electroluminescence layer 25 and a transparent electrode 26 are provided thereon in common to each sub-pixel. Separately, a filter substrate having, on a transparent substrate 29, a color filter layer (CF layer 23) that is area-divided corresponding to the color of each sub-pixel and each sub-sub-pixel is prepared, and this is pasted by an adhesive layer 28 so that the CF layer 23 faces the transparent electrode 26. When an electric current is applied to the obtained display, light emitted in the white organic electroluminescence layer 25 transmits through the CF layer 23 of each color, and then, the resulting R, G, and B lights transmit through the transparent substrate 29 to be emitted to the outside. In the W sub-pixel, the light is observed as a white light by mixing of lights of three colors from the R, G, and B sub-sub-pixels. The structure is an example of a top emission type organic EL display. According to the structure, since outside light-reflection is prevented by the color filters of the W sub-pixel unit, the contrast of an image displayed in a light room does not decrease, and thus reproduction of a high quality image with a clear black display region can be attained.

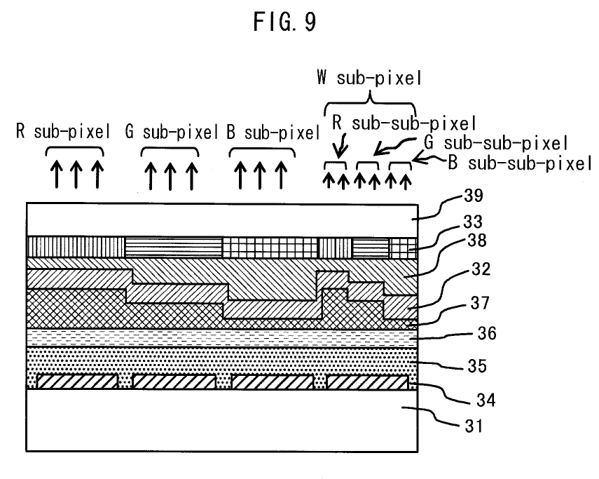

FIG. 9 is a schematic configuration diagram illustrating a cross sectional view of the structure of one pixel according to still another embodiment of the invention.

On a substrate 31, a light-reflection electrode 34 that is pattered corresponding to each sub-pixel and each sub-sub-pixel is provided. A white organic electroluminescence layer 35 and a transparent electrode 36 are provided thereon in common to each sub-pixel. An optical path length-adjusting layer 37 provided thereon is formed of a light transmitting material and is disposed while changing the thickness according to the wavelength of each emitted light of the R, G, B sub-pixel units and the R, G, B sub-sub-pixel units. A layer that partially transmits light and partially reflects light 32 is provided thereon in common to each sub-pixel. The thickness of the optical path length-adjusting layer 37 is adjusted so that the distance between the light-reflection electrode 34 and the layer that partially transmits light and partially reflects light 32 becomes an optical distance in which each of the R, G, and B lights resonates.

Separately, a filter substrate having, on a transparent substrate 39, a color filter layer (CF layer 33) that is area-divided corresponding to the color of each sub-pixel and each sub-sub-pixel is prepared, and this is pasted by an adhesive layer 28 so that the CF layer 33 faces the layer that partially transmits light and partially reflects light 32.

Light emitted in the white organic EL layer 35 by applying an electric current is repeatedly reflected between the light-reflection electrode 34 and the layer that partially transmits light and partially reflects light 32, then R, G, and B lights each having a resonant wavelength transmit through the layer that partially transmits light and partially reflects light 32, and then each light transmits through the transparent substrate 39 via the R, G, or B filter to be emitted to the outside. In the W sub-pixel unit, the light is observed as a white light by mixing of the R, G, and B lights.

According to the structure of the embodiment, since outside light-reflection is prevented by the color filters of the W sub-pixel unit, the contrast of an image displayed in a light room does not decrease, which allows reproduction of a high quality image with a clear black display region. Although the brightness decreases due to absorption of unnecessary wavelengths of the R, G, and B filters, the intensity of a required wavelength is amplified by the resonator, and thus a high brightness light can be taken out.

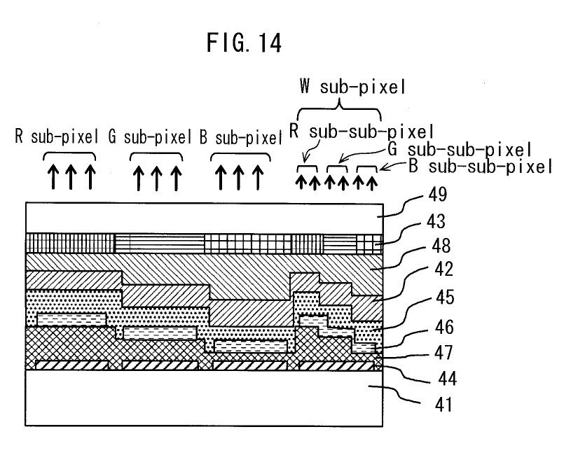

FIG. 14 is a schematic configuration diagram illustrating a cross sectional view of the structure of one pixel according to still another embodiment of the invention.

On a substrate 41, a light-reflection electrode 44 that is pattered corresponding to each sub-pixel and each sub-sub-pixel is provided. An optical path length-adjusting layer 47 provided thereon is formed of a light transmitting material, and is disposed while changing the thickness according to the wavelength of each emitted light of the R, G, B sub-pixel units and the R, G, B sub-sub-pixel units. A transparent electrode 46, a white organic electroluminescence layer 45 and an electrode that partially transmits light and partially reflects light 42 are provided thereon in common to each sub-pixel. The thickness of the optical path length-adjusting layer 47 is adjusted so that the distance between the light-reflection electrode 44 and the electrode that partially transmits light and partially reflects light 42 becomes an optical distance in which each of the R, G, and B lights resonates.

Separately, a filter substrate having, on a transparent substrate 49, a color filter layer (CF layer 43) that is area-divided corresponding to the color of each sub-pixel and each sub-sub-pixel is prepared, and this is pasted by an adhesive layer 48 so that the CF layer 43 faces the electrode that partially transmits light and partially reflects light 42.

Light emitted in the white organic EL layer 45 by applying an electric current is repeatedly reflected between the light-reflection layer 44 and the electrode that partially transmits light and partially reflects light 42, then R, G, and B lights each having a resonant wavelength transmit through the electrode that partially transmits light and partially reflects light 42, and then each light transmits through the transparent substrate 49 via the R, G, or B filter to be emitted to the outside. In the W sub-pixel unit, the light is observed as a white light by mixing of the R, G, and B lights.

According to the structure of the invention, since outside light-reflection is prevented by the color filters of the W sub-pixel unit, the contrast of an image displayed in a light room does not decrease, which allows reproduction of a high quality image with a clear black display region. Although the brightness decreases due to absorption of unnecessary wavelengths of the R, G, and B filters, the intensity of a required wavelength is amplified by the resonator, and thus a high brightness light can be taken out.

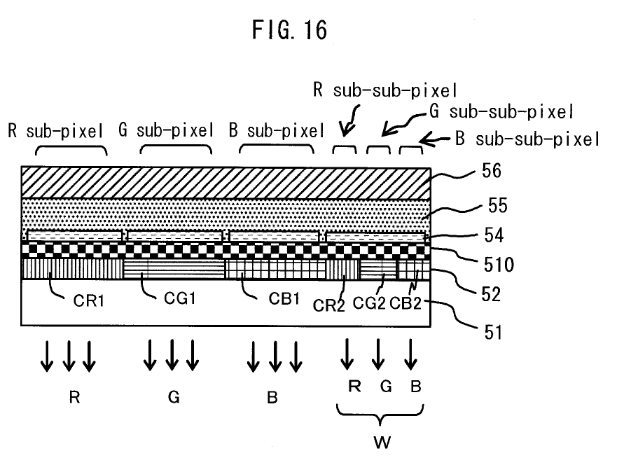

FIG. 16 is a schematic configuration diagram illustrating a cross sectional view of the structure of one pixel according to still another embodiment of the invention.

On a transparent substrate 51, a color filter layer (CF layer 52) is provided corresponding to the color of each sub-pixel. An R filter (CR1), a G filter (CG1), and a B filter (CB1) are provided corresponding to the divided R, G, B sub-pixel units, respectively. Also in the W sub-pixel, an R filter (CR2), a G filter (CG2), and a B filter (CB2) are provided corresponding to the R, G, B sub-sub-pixel units, respectively.

A light extraction structure layer 510 is provided on the CF layer 52. The light extraction structure layer is a layer for suppressing total reflection caused by a refractive-index difference between the layer and each constitution layer provided at both sides of the layer and increasing the amount of light emitted to the outside.

On the light extraction structure layer 510, a patterned transparent electrode 54 is provided, and a white organic electroluminescence layer 55 and a light-reflection electrode 56 are provided thereon in common to each sub-pixel. Light emitted in the white organic electroluminescence layer 55 by applying an electric current transmits through the transparent electrode 54 and the light extraction structure layer 510, then R, G, and B lights transmit by the CF layer 52 of each color, and then the R, G, and B lights transmit through the substrate 51 to be emitted to the outside. In the W sub-pixel, the light is observed as a white light by mixing of lights of three colors from the R, G, and B sub-sub-pixels. Since outside light-reflection is prevented by the color filters of the W sub-pixel unit, the contrast of an image displayed in a light room does not decrease, and thus reproduction of a high quality image with a clear black display region can be attained.

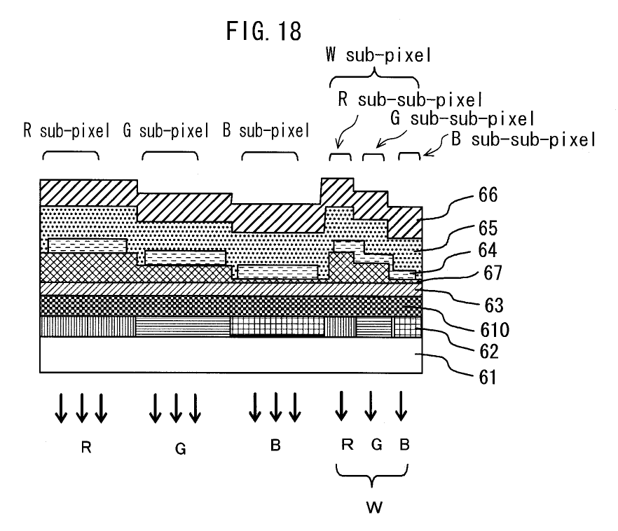

FIG. 18 is a schematic configuration diagram illustrating a cross sectional view of the structure of one pixel according to still another embodiment of the invention.

On a transparent substrate 61, a color filter layer (CF layer 62) is provided corresponding to the color of each sub-pixel. An R filter (CR1), a G filter (CG1), and a B filter (CB1) are provided corresponding to the divided R, G, B sub-pixel units, respectively. Also in the W sub-pixel, an R filter (CR2), a G filter (CG2), and a B filter (CB2) are provided corresponding to the R, G, B sub-sub-pixel units, respectively.

A light extraction structure layer 610 is provided on the CF layer 62. The light extraction structure layer is a layer for suppressing total reflection caused by a refractive-index difference between the layer and each constitution layer provided at both sides of the layer and increasing the amount of light emitted to the outside.

On the light extraction structure layer 610, a layer that partially transmits light and partially reflects light 63 is provided in common to each sub-pixel and each sub-sub-pixel. An optical path length-adjusting layer 67 provided thereon is formed of a light transmitting material, and is disposed while changing the thickness according to the wavelength of each emitted light of the R, G, B sub-pixel units and the R, G, B sub-sub-pixel units. Thereon, a transparent electrode 64 that is pattered corresponding to each sub-pixel is provided. A white organic electroluminescence layer 65 and a light-reflection electrode 66 are provided thereon in common to each sub-pixel. The distance between the light-reflection electrode 66 and the layer that partially transmits light and partially reflects light 63 is designed a thickness of the optical path length-adjusting layer 67 to be an optical distance in which each of the R, G, and B lights resonates.

Light emitted in the white organic EL layer 65 by applying an electric current is repeatedly reflected between the light-reflection electrode 66 and the layer that partially transmits light and partially reflects light 63, then R, G, and B lights each having a resonant wavelength transmit through the layer that partially transmits light and partially reflects light 63 and the light extraction structure layer 610, and then each light transmits through the transparent substrate 61 via the R, G, or B filter to be emitted to the outside. In the W sub-pixel unit, the light is observed as a white light by mixing of the R, G, and B lights.

According to the structure of the invention, since outside light-reflection is prevented by the color filters of the W sub-pixel unit, the contrast of an image displayed in a light room does not decrease, which allows reproduction of a high quality image with a clear black display region. Although the brightness decreases due to absorption of unnecessary wavelengths of the R, G, and B filters, the intensity of a required wavelength is amplified by the resonator, and thus a high brightness light can be taken out.

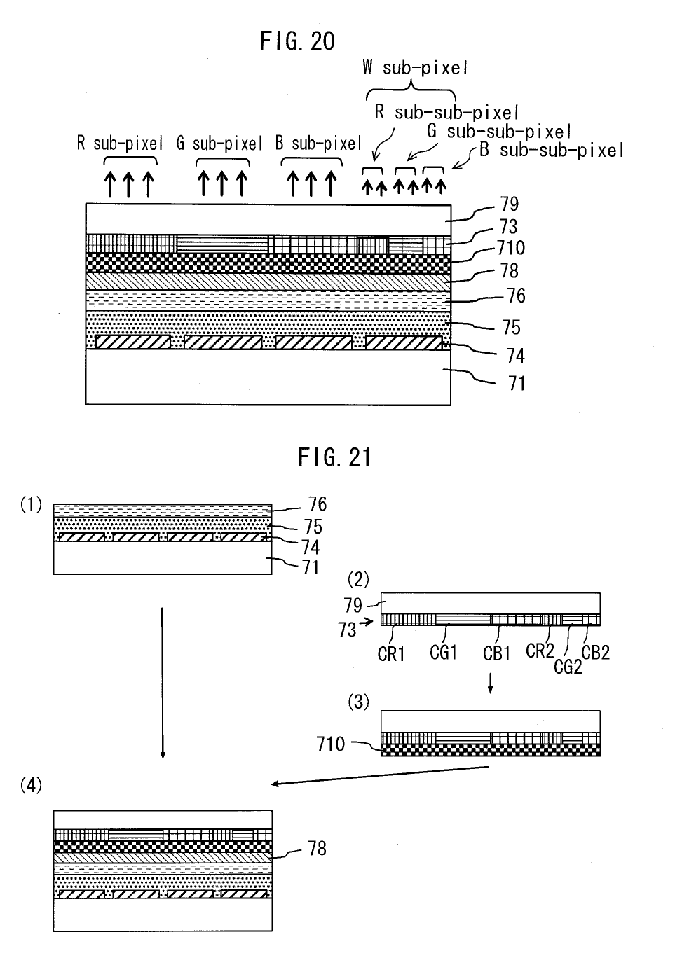

FIG. 20 is a schematic configuration diagram illustrating a cross sectional view of still another structure of one pixel according to the invention.

On a substrate 71, a patterned light-reflection electrode 74 is provided, and a white organic electroluminescence layer 75 and a transparent electrode 76 are provided thereon in common to each sub-pixel. Separately, a filter substrate having, on a transparent substrate 79, a color filter layer (CF layer 73) that is area-divided corresponding to the color of each sub-pixel and each sub-sub-pixel, and a light extraction structure layer 710 is prepared, and this is pasted by an adhesive layer 78 so that the light extraction structure layer 710 faces the transparent electrode 76. When an electric current is applied to the obtained display, light emitted in the white organic electroluminescence layer 75 transmits through the CF layer 73 of each color, and then the resulting R, G, and B lights transmit through the transparent substrate 79 to be emitted to the outside. In the W sub-pixel, the light is observed as a white light by mixing of lights of three colors from the R, G, and B sub-sub-pixels. The structure is an example of a top emission type organic EL display. According to the structure, since outside light-reflection is prevented by the color filters of the W sub-pixel unit, the contrast of an image displayed in a light room does not decrease, and thus reproduction of a high quality image with a clear black display region can be attained.

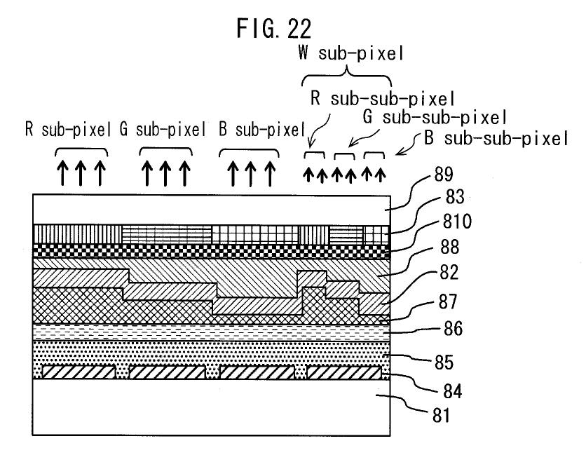

FIG. 22 is a schematic configuration diagram illustrating a cross sectional view of the structure of one pixel according to still another embodiment of the invention.

On a substrate 81, a light-reflection electrode 84 that is pattered corresponding to each sub-pixel and each sub-sub-pixel is provided. A white organic electroluminescence layer 85 and a transparent electrode 86 are provided thereon in common to each sub-pixel. An optical path length-adjusting layer 87 provided thereon is formed of a light transmitting material and is disposed while changing the thickness according to the wavelength of each emitted light of the R, G, B sub-pixel units and the R, G, B sub-sub-pixel units. A layer that partially transmits light and partially reflects light 82 is provided thereon in common to each sub-pixel. The thickness of the optical path length-adjusting layer 87 is adjusted so that the distance between the light-reflection electrode 84 and the layer that partially transmits light and partially reflects light 82 is to be an optical distance in which each of the R, G, and B lights resonates.

Separately, a filter substrate having, on a transparent substrate 89, a color filter layer (CF layer 83) that is area-divided corresponding to the color of each sub-pixel and each sub-sub-pixel, and a light extraction structure layer 810 is prepared, and this is pasted by an adhesive layer 88 so that the light extraction structure layer 810 faces the layer that partially transmits light and partially reflects light 82.

Light emitted in the white organic EL layer 85 by applying an electric current is repeatedly reflected between the light-reflection electrode 84 and the layer that partially transmits light and partially reflects light 82, then R, G, and B lights each having a resonant wavelength transmit through the layer that partially transmits light and partially reflects light 82, and then each light transmits through the transparent substrate 89 via the R, G, or B filter to be emitted to the outside. In the W sub-pixel unit, the light is observed as a white light by mixing of the R, G, and B lights.

According to the structure of the invention, since outside light-reflection is prevented by the color filters of the W sub-pixel unit, the contrast of an image displayed in a light room does not decrease, which allows reproduction of a high quality image with a clear black display region. Although the brightness decreases due to absorption of unnecessary wavelengths of the R, G, and B filters, the intensity of a required wavelength is amplified by the resonator, and thus a high brightness light can be taken out.

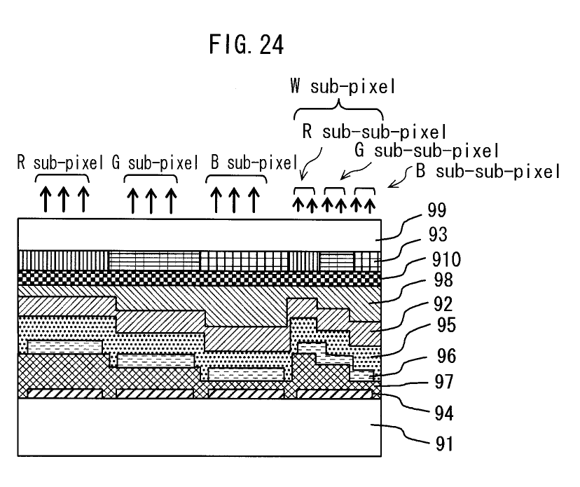

FIG. 24 is a schematic configuration diagram illustrating a cross sectional view of the structure of one pixel according to still another embodiment of the invention.

On a substrate 91, a light-reflection layer 94 that is pattered corresponding to each sub-pixel and each sub-sub-pixel is provided. An optical path length-adjusting layer 97 provided thereon is formed of a light transmitting material, and is disposed while changing the thickness according to the wavelength of each emitted light of the R, G, B sub-pixel units and the R, G, B sub-sub-pixel units. A patterned transparent electrode 96 is provided thereon, and a white organic electroluminescence layer 95 and an electrode that partially transmits light and partially reflects light 92 are provided thereon in common to each sub-pixel. The thickness of the optical path length-adjusting layer 97 is adjusted so that the distance between the light-reflection layer 94 and the electrode that partially transmits light and partially reflects light 92 becomes an optical distance in which each of the R, G, and B lights resonates.

Separately, a filter substrate having, on a transparent substrate 99, a color filter layer (CF layer 93) that is area-divided corresponding to the color of each sub-pixel and each sub-sub-pixel, and a light extraction structure layer 910 is prepared, and this is pasted by an adhesive layer 98 so that the light extraction structure layer 910 faces the electrode that partially transmits light and partially reflects light 92.

Light emitted in the white organic EL layer 95 by applying an electric current is repeatedly reflected between the light-reflection layer 94 and the electrode that partially transmits light and partially reflects light 92, then R, G, and B lights each having a resonant wavelength transmit through the electrode that partially transmits light and partially reflects light 92, and then each light transmits through the transparent substrate 99 via the R, G, or B filter to be emitted to the outside. In the W sub-pixel unit, the light is observed as a white light by mixing of the R, G, and B lights.

According to the structure of the invention, since outside light-reflection is prevented by the color filters of the W sub-pixel unit, the contrast of an image displayed in a light room does not decrease, which allows reproduction of a high quality image with a clear black display region. Although the brightness decreases due to absorption of unnecessary wavelengths of the R, G, and B filters, the intensity of a required wavelength is amplified by the resonator, and thus a high brightness light can be taken out.

### 2. Color Filter Layer

The color filter used in the invention is not particularly limited. Conventionally, various color filters having a fine pattern are known, and various methods for producing the same are also known. In the invention, the color filters can be preferably provided according to the known methods for producing color filters.

The color filter for use in the invention can be provided by forming a fine pattern in formation processes for the display containing the light-emitting layer as shown in FIGS. 6, 7, 16, and 18. Or, as shown in FIGS. 8, 9, 14, 20, 22, and 24, a color filter of a fine pattern may be produced beforehand, and then pasted during the formation processes for the display containing the light-emitting layer.

### 3. Optical Path Length-Adjusting Layer

In the invention, it is preferable to internally introduce an optical path length-adjusting layer to form a resonator.

As a material for use in the optical path length-adjusting layer of the invention, either of an inorganic material or an organic material can be used. An inorganic insulating material is preferably used.

A light transmitting inorganic insulating material includes various known metal oxides, metal nitrides, metal fluorides and the like.

Specific examples of metal oxides include MgO, SiO₂, Al₂O₃, Y₂O₃, TiO₂ and the like. Specific examples of metal nitrides include SiNₓ, SiNₓO_{y}, AlN and the like. Specific examples of metal fluorides include MgF₂, LiF, AlF₃, CaF₂, BaF₂ and the like. Moreover, mixtures thereof may be acceptable.

As an organic material, a film forming polymer is preferably used. Examples of a film forming polymer include polycarbonate, polyacrylate, a silicone resin, and polyvinyl butyral.

The thickness of the optical path length-adjusting layer is adjusted so that each sub-pixel has an optical distance in which light of a specific wavelength can efficiently resonate. Therefore, the resonating optical distance is determined by the refractive index, composition, and thickness of a material interposed between the light-reflection layer and the layer that partially transmits light and partially reflects light, and is not determined only by the optical path length-adjusting layer. Considering the structure of a generally used organic EL layer, the thickness of the optical path length-adjusting layer of each of the R sub-pixel unit and the R sub-sub-pixel unit is, in terms of physical thickness, preferably from 30 nm to 1000 nm, more preferably from 150 nm to 350 nm, and even more preferably from 200 nm to 250 nm. The thickness of the optical path length-adjusting layer of each of the G sub-pixel unit and the G sub-sub-pixel unit is, in terms of physical thickness, preferably from 5 nm to 800 nm, more preferably from 100 nm to 250 nm, and even more preferably from 150 nm to 200 nm. The thickness of the optical path length-adjusting layer of each of the B sub-pixel unit and the B sub-sub-pixel unit is, in terms of physical thickness, preferably from 0 nm to 600 nm, more preferably from 50 nm to 200 nm, and even more preferably from 100 nm to 150 nm.

A method for forming the optical path length-adjusting layer is not particularly limited. For example, a vacuum deposition method, a sputtering method, a reactive-sputtering method, an MBE (molecular beam epitaxy) method, a cluster ion beam method, an ion plating method, a plasma polymerization method (high-frequency excitation ion plating method), a plasma CVD (chemical vapor deposition) method, a laser-CVD method, a thermal CVD method, a gas source CVD method, a coating method, a printing method, or a transfer method is applicable.

### 4. Organic Electroluminescence Element

An organic electroluminescence element in the present invention has an organic electroluminescence layer between a pair of electrodes. An organic electroluminescence layer includes, in addition to a light-emitting layer, generally known organic compound layer such as a hole-transport layer, an electron-transport layer, a blocking layer, an electron-injection layer, a hole-injection layer or the like.

In the following, the organic electroluminescence element of the present invention will be described in detail.

1) Layer Configuration

<Electrode>

At least one of a pair of electrodes of the organic electroluminescence element of the present invention is a transparent electrode, and the other one is a rear surface electrode. The rear surface electrode may be transparent or non-transparent.

<Configuration of Organic Compound Layer>

A layer configuration of the organic compound layer can be appropriately selected, without particular limitation, depending on an application of the organic electroluminescence element and a purpose thereof. However, the organic compound layers are preferably formed on the transparent electrode or the rear surface electrode. In these cases, the organic compound layers are formed on front surfaces or one surface on the transparent electrode or the rear surface electrode.

A shape, size and thickness of the organic compound layers can be appropriately selected, without particular limitation, depending on an object thereof.

Examples of specific layer configurations include those cited below, but the present invention is not limited to those examples

Anode/hole-transport layer/light-emitting layer/electron-transport layer/cathode,

Anode/hole-transport layer/light-emitting layer/blocking layer/electron-transport layer/cathode,

Anode/hole-transport layer/light-emitting layer/blocking layer/electron-transport layer/electron-injection layer/cathode,

Anode/hole-injection layer/hole-transport layer/light-emitting layer/blocking layer/electron-transport layer/cathode, and

Anode/hole-injection layer/hole-transport layer/light-emitting layer/blocking layer/electron-transport layer/electron-injection layer/cathode.

In the following, each layer will be described in detail.

2) Hole-Transport Layer

The hole-transport layer used in the present invention includes a hole transporting material. For the hole transporting material, any material can be used without particular limitation as far as it has either one of a function of transporting holes or a function of blocking electrons injected from the cathode. As the hole transporting material that can be used in the present invention, either one of a low molecular weight hole transporting material or a polymer hole transporting material can be used.

Specific examples of the hole transporting material that can be used in the present invention include a carbazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidene-based compound, a porphyrin-based compound, a polysilane-based compound, a poly(N-vinylcarbazole) derivative, an aniline-based copolymer, electric conductive polymers or oligomers such as a thiophene oligomer and polythiophene, and polymer compounds such as a polythiophene derivative, a polyphenylene derivative, a polyphenylenevinylene derivative, a polyfluorene derivative or the like.

These compounds may be used alone or in a combination of two or more of them.

A thickness of the hole-transport layer is preferably from 10 nm to 400 nm and more preferably from 50 nm to 200 nm.

3) Hole-Injection Layer

In the present invention, a hole-injection layer may be disposed between the hole-transport layer and the anode.

The hole-injection layer is a layer that makes it easy for holes to be injected from the anode to the hole-transport layer, and specifically, a material having a small ionization potential among the hole transporting materials cited above is preferably used. For instance, a phthalocyanine compound, a porphyrin compound and a star-burst type triarylamine compound can be preferably used.

A film thickness of the hole-injection layer is preferably from 1 nm to 300 nm.

4) Light-Emitting Layer

The light-emitting layer used in the present invention comprises at least one light emitting material, and may comprise as necessary other compounds such as a hole transporting material, an electron transporting material, and a host material.

Any of light emitting materials can be used without particular limitation. Either of fluorescent light-emitting materials or phosphorescent light-emitting materials can be used, but the phosphorescent light-emitting materials are preferred in view of the light-emission efficiency.

As a light emitting material, a white light emitting material may be used singly, or two or more light emitting materials may be used in combination to obtain a white light. When two or more light emitting materials are used in combination, a combination of colors of light emitted from the light emitting materials is not particularly limited. Examples of combinations include a combination of a blue light emitting material and a yellow light emitting material, a combination of a blue light emitting material, a green light emitting material and a red light emitting material and the like.

Examples of the above-described fluorescent light-emitting materials include a benzoxazole derivative, a benzimidazole derivative, a benzothiazole derivative, a styrylbenzene derivative, a polyphenyl derivative, a diphenylbutadiene derivative, a tetraphenylbutadiene derivative, a naphthalimide derivative, a coumarin derivative, a perylene derivative, a perinone derivative, an oxadiazole derivative, an aldazine derivative, a pyralidine derivative, a cyclopentadiene derivative, a bis-styrylanthracene derivative, a quinacridone derivative, a pyrrolopyridine derivative, a thiadiazolopyridine derivative, a styrylamine derivative, aromatic dimethylidene compounds, a variety of metal complexes represented by metal complexes or rare-earth complexes of 8-quinolinol derivative, polymer compounds such as a polythiophene derivative, a polyphenylene derivative and a polyphenylenevinylene derivative, and a polyfluorene derivative, and the like. These compounds may be used alone or in a combination of two or more of them.

The phosphorescent light-emitting material is not particularly limited, but an ortho-metal complex or a porphyrin metal complex is preferred.

The ortho-metal complex referred to herein is a generic designation of a group of compounds described in, for instance, Akio Yamamoto, Yuki Kinzoku Kagaku, Kiso to Oyo (“Organometallic Chemistry, Fundamentals and Applications”) (Shokabo, 1982), pages 150 to 232, and H. Yersin, Photochemistry and Photophysics of Coordination Compounds (New York: Springer-Verlag, 1987), pages 71-77 and pages 135-146. The ortho-metal complex can be advantageously used as a light-emitting material because high brightness and excellent light-emission efficiency can be obtained.

As a ligand that forms the ortho-metal complex, various ligands can be cited and are described in the above-mentioned literature as well. Examples of preferable ligands include a 2-phenylpyridine derivative, a 7,8-benzoquinoline derivative, a 2-(2-thienyl)pyridine derivative, a 2-(1-naphtyl)pyridine derivative and a 2-phenylquinoline derivative. The derivatives may be substituted by a substituent as needs arise. Furthermore, the ortho-metal complex may have other ligands than the ligands mentioned above.

An ortho-metal complex used in the present invention can be synthesized according to various known processes such as those described in Inorg. Chem., 1991, Vol. 30, pp. 1685; Inorg. Chem., 1988, Vol. 27, page 3464; Inorg. Chem., 1994, Vol. 33, page 545; Inorg. Chim. Acta, 1991, Vol. 181, page 245; J. Organomet. Chem., 1987, Vol. 335, page 293 and J. Am. Chem. Soc., 1985, Vol. 107, page 1431.

Among the ortho-metal complexes, compounds emitting light from a triplet exciton can be preferably employed in the present invention from the viewpoint of improving light-emission efficiency.

Furthermore, among the porphyrin metal complexes, a porphyrin platinum complex is preferable.

The phosphorescent light emitting materials may be used alone or in a combination of two or more of them. Furthermore, a fluorescent light-emitting material and a phosphorescent light-emitting material may be simultaneously used.

A host material is a material that has a function of causing an energy transfer from an excited state thereof to the fluorescent light-emitting material or the phosphorescent light-emitting material to cause light emission from the fluorescent light-emitting material or the phosphorescent light-emitting material.

As the host material, as long as a compound can transfer exciton energy to a light emitting material, any compound can be appropriately selected and used depending on an objectn without particular limitation. Specific examples thereof include: a carbazole derivative; a triazole derivative; an oxazole derivative; an oxadiazole derivative; an imidazole derivative; a polyarylalkane derivative; a pyrazoline derivative; a pyrazolone derivative; a phenylenediamine derivative; an arylamine derivative; an amino-substituted chalcone derivative; a styrylanthracene derivative; a fluorenone derivative; a hydrazone derivative; a stilbene derivative; a silazane derivative; an aromatic tertiary amine compound; a styrylamine compound; an aromatic dimethylidene-based compound; a porphyrin-based compound; an anthraquinonedimethane derivative; an anthrone derivative; a diphenylquinone derivative; a thiopyran dioxide derivative; a carbodiimide derivative; a fluorenylidenemethane derivative; a distyrylpyrazine derivative; aromatic ring tetracarboxylic anhydrides such as naphthalene, perylene or the like; a phthalocyanine derivative; a variety of metal complexes typified by metal complexes of 8-quinolinol derivative, metal phthalocyanine, and metal complexes with benzoxazole or benzothiazole as a ligand; polysilane compounds; a poly(N-vinylcarbazole) derivative; an aniline-based copolymer; electric conductive polymers or oligomers such as a thiophene oligomer and polythiophene; polymer compounds such as a polythiophene derivative, a polyphenylene derivative, a polyphenylenevinylene derivative and a polyfluorene derivative; and like. These compounds can be used alone or in a combination of two or more of them.

A content of the host material in the light-emitting layer is preferably in a range of 0% by weight to 99.9% by weight, and more preferably in a range of 0% by weight to 99.0% by weight.

5) Blocking Layer

In the present invention, a blocking layer may be disposed between the light-emitting layer and the electron-transport layer. The blocking layer is a layer that inhibits excitons generated in the light-emitting layer from diffusing and holes from penetrating to a cathode side.

A material that is used in the blocking layer may be a general electron transporting material, as long as it can receive electrons from the electron-transport layer and deliver them to the light-emitting layer, without being particularly limited. Examples thereof include a triazole derivative; an oxazole derivative; an oxadiazole derivative; a fluorenone derivative; an anthraquinodimethane derivative; an anthrone derivative; a diphenylquinone derivative; a thiopyran dioxide derivative; a carbodiimide derivative; a fluorenylidenemethane derivative; a distyrylpyrazine derivative; aromatic ring tetracarboxylic anhydrides of naphthalene, perylene or the like; a phthalocyanine derivative; a variety of metal complexes typical in metal complexes of 8-quinolinol derivative, metal phthalocyanine, and metal complexes with benzoxazole or benzothiazole as a ligand; electric conductive polymers oligomers such as an aniline-based copolymer, a thiophene oligomer and polythiophene; and polymer compounds such as a polythiophene derivative, a polyphenylene derivative, a polyphenylenevinylene derivative and a polyfluorene derivative. These can be used alone or in a combination of two or more of them.

6) Electron-Transport Layer

In the present invention, an electron-transport layer including an electron transporting material can be disposed.

The electron transporting material can be used without particular limitation, as long as it has either one of a function of transporting electrons or a function of blocking holes injected from the an anode. The electron transporting materials that are described above in the explanation of the blocking layer can be preferably used.

A thickness of the electron-transport layer is preferably from 10 nm to 200 nm, and more preferably from 20 nm to 80 nm.

In the case that the thickness exceeds 200 nm, the driving voltage increases in some cases. In the case that it is less than 10 nm, the light-emission efficiency of the light-emitting element may be greatly deteriorated, which is not preferable.

7) Electron-Injection Layer

In the present invention, an electron-injection layer can be disposed between the electron-transport layer and the cathode.

The electron-injection layer is a layer by which electrons can be readily injected from the cathode to the electron-transport layer. Specifically, lithium salts such as lithium fluoride, lithium chloride and lithium bromide; alkali metal salts such as sodium fluoride, sodium chloride and cesium fluoride; and electrically insulating metal oxides such as lithium oxide, aluminum oxide, indium oxide and magnesium oxide can be preferably used.

A film thickness of the electron-injection layer is preferably from 0.1 nm to 5 nm.

8) Substrate

The substrate to be applied in the present invention is preferably impermeable to moisture or very slightly permeable to moisture. Furthermore, the substrate preferably does not scatter or attenuate light emitted from the organic compound layer. Specific examples of materials for the substrate include inorganic materials such as YSZ (zirconia-stabilized yttrium) and glass; and organic materials including polyesters such as polyethylene terephthalate, polybutylene phthalate and polyethylene naphthalate, and synthetic resins such as polystyrene, polycarbonate, polyethersulfon, polyarylate, aryldiglycolcarbonate, polyimide, polycycloolefine, norbornene resin, poly(chlorotrifluoroethylene), and the like.

In case of employing an organic material, it is preferred to use a material excellent in heat resistance, dimensional stability, solvent-resistance, electric insulation performance, workability, low gas-permeability, and low moisture-absorption. These can be used alone or in a combination of two or more of them.

There is no particular limitation as to the shape, the structure, the size and the like of the substrate, but it may be suitably selected according to the application, the purposes and the like of the light-emitting element. In general, a plate-like substrate is preferred as the shape of the substrate. The structure of the substrate may be a monolayer structure or a laminated structure. Furthermore, the substrate may be formed from a single member or from two or more members.

Although the substrate may be transparent and colorless, or transparent and colored, it is preferred that the substrate is transparent and colorless from the viewpoint that the substrate does not scatter or attenuate light emitted from the light-emitting layer.

A moisture permeation preventive layer (gas barrier layer) may be provided on the front surface or the back surface (on the transparent electrode side) of the substrate. For a material of the moisture permeation preventive layer (gas barrier layer), inorganic substances such as silicon nitride and silicon oxide may be preferably applied. The moisture permeation preventive layer (gas barrier layer) may be formed in accordance with, for example, a high-frequency sputtering method or the like.

The substrate may have a hard-coat layer, an under-coat layer or the like as necessary.

9) Electrodes

Concerning the pair of electrodes in the invention, either one of the first electrode or the second electrode can be an anode or a cathode. It is preferable that the first electrode is the anode and the second electrode is the cathode.

<Anode>

The anode in the present invention may generally have a function as an anode for supplying holes to the organic compound layer, and while there is no particular limitation as to the shape, the structure, the size and the like of the anode, it may be suitably selected from among well-known electrodes according to the application and the purpose of the light-emitting element.

As materials for the anode, for example, metals, alloys, metal oxides, electric conductive compounds, and mixtures thereof are preferably used, wherein those having a work function of 4.0 eV or more are preferred. Specific examples of the anode materials include semiconductive metal oxides such as tin oxides doped with antimony, fluorine or the like (ATO and FTO), tin oxide, zinc oxide, indium oxide, indium tin oxide (ITO), and indium zinc oxide (IZO); metals such as gold, silver, chromium, and nickel; mixtures or laminates of these metals and the electric conductive metal oxides; inorganic electric conductive materials such as copper iodide, and copper sulfide; organic electric conductive materials such as polyaniline, polythiophene, and polypyrrole; and laminates of these inorganic or organic electric conductive materials with ITO.

The anode may be formed on the substrate, for example, in accordance with a method which is appropriately selected from among wet methods such as a printing method, a coating method and the like; physical methods such as a vacuum deposition method, a sputtering method, an ion plating method and the like; and chemical methods such as CVD and plasma CVD methods and the like in consideration of the suitability to a material constituting the anode. For instance, when ITO is selected as a material for the anode, the anode may be formed in accordance with a DC or high-frequency sputtering method, a vacuum deposition method, an ion plating method or the like. Further, when an organic electric conductive compound is selected as a material of the anode, the anode may be formed in accordance with a wet film forming method.

A position at which the anode is to be formed in the light-emitting element is not particularly limited, but it may be suitably selected according to the application and the purpose of the light-emitting element. The anode may be formed on either the whole surface or a part of the surface on either side of the substrate.

For patterning to form the anode, a chemical etching method such as photolithography, a physical etching method such as etching by laser, a method of vacuum deposition or sputtering through superposing masks, and a lift-off method or a printing method may be applied.

A thickness of the anode may be suitably selected dependent on the material constituting the anode, and is not definitely decided, but it is usually in a range of from 10 nm to 50 μm, and preferably from 50 nm to 20 μm.

A value of electric resistance of the anode is preferably 10³ Ω/□ or less, and more preferably 10² Ω/□ or less.

The anode may be colorless and transparent or colored and transparent. For extracting luminescence from the transparent anode side, it is preferred that a light transmittance of the anode is 60% or higher, and more preferably 70% or higher. The light transmittance in the present invention can be measured by means well known in the art using a spectrophotometer.

Concerning the anode, there is a detailed description in “TOUMEI DENNKYOKU-MAKU NO SHINTENKAI (Novel Developments in Transparent Electrode Films)” edited by Yutaka Sawada and published by C.M.C. in 1999, the contents of which are incorporated by reference herein. In the case where a plastic substrate of a low heat resistance is applied, it is preferred that ITO or IZO is used to obtain an anode prepared by forming the film at a low temperature of 150° C. or lower.

<Cathode>

The cathode in the present invention may generally have a function as an electrode for injecting electrons to the organic compound layer, and there is no particular limitation as to the shape, the structure, the size and the like. Accordingly, the cathode may be suitably selected from among well-known electrodes according to the application and the purpose of the light-emitting element.

As the materials constituting the cathode, for example, metals, alloys, metal oxides, electric conductive compounds, and mixtures thereof may be used, wherein materials having a work function of 4.5 eV or less are preferred. Specific examples thereof include alkali metals (e.g., Li, Na, K, Cs or the like); alkaline earth metals (e.g., Mg, Ca or the like); gold; silver; lead; aluminum; sodium-potassium alloys; lithium-aluminum alloys; magnesium-silver alloys; rare earth metals such as indium and ytterbium; and the like. They may be used alone, but it is preferred that two or more of them are used in combination from the viewpoint of satisfying both of stability and electron injectability.

Among these, as the materials for constituting the cathode, alkaline metals or alkaline earth metals are preferred in view of electron injectability, and materials containing aluminum as the major component are preferred in view of excellent preservation stability. The term “material containing aluminum as the major component” refers to a material that material exists in the form of aluminum alone; alloys comprising aluminum and 0.01% by mass to 10% by mass of an alkaline metal or an alkaline earth metal; or mixtures thereof (e.g., lithium-aluminum alloys, magnesium-aluminum alloys and the like).

As for materials for the cathode, they are described in detail in JP-A Nos. 2-15595 and 5-121172, the contents of which are incorporated by reference herein.

A method for forming the cathode is not particularly limited, but it may be formed on the substrate described above in accordance with a well-known method. For instance, the cathode may be formed in accordance with a method which is appropriately selected from among wet methods such as a printing method, a coating method and the like; physical methods such as a vacuum deposition method, a sputtering method, an ion plating method and the like; and chemical methods such as CVD and plasma CVD methods and the like, while taking the suitability to a material constituting the cathode into consideration.

For example, when a metal (or metals) is (are) selected as a material (or materials) for the cathode, one or two or more of them may be applied at the same time or sequentially in accordance with a sputtering method or the like.

For patterning to form the cathode, a chemical etching method such as photolithography, a physical etching method such as etching by laser, a method of vacuum deposition or sputtering through superposing masks, and a lift-off method or a printing method may be applied.

In the organic electroluminescence element of the present invention, a position at which the cathode is to be formed is not particularly limited, and it may be suitably selected according to the application and purpose of the light-emitting element. The cathode is preferably formed on the organic compound layer. In this case, the cathode may be formed on either the whole or a part of the organic compound layer.

Furthermore, a dielectric material layer made of a fluoride or the like of an alkaline metal or an alkaline earth metal may be inserted between the cathode and the organic compound layer with a thickness of 0.1 nm to 5 nm.

A thickness of the cathode may be suitably selected dependent on materials for constituting the cathode and is not definitely decided, but it is usually in a range of from 10 nm to 5 μm, and preferably from 50 nm to 1 μm.

Moreover, the cathode may be transparent or opaque. The transparent cathode may be formed by preparing a material for the cathode with a small thickness of from 1 nm to 10 nm, and further laminating a transparent electric conductive material such as ITO or IZO thereon.

10) Protective Layer

In the present invention, the whole organic EL element may be protected by a protective layer.

A material contained in the protective layer may be one having a function to prevent penetration of substances such as moisture and oxygen, which accelerate deterioration of the element, into the element.

Specific examples thereof include metals such as In, Sn, Pb, Au, Cu, Ag, Al, Ti, Ni and the like; metal oxides such as MgO, SiO, SiO₂, Al₂O₃, GeO, NiO, CaO, BaO, Fe₂O₃, Y₂O₃, TiO₂ and the like; metal nitrides such as SiNₓ, SiNₓO_{y} and the like; metal fluorides such as MgF₂, LiF, AlF₃, CaF₂ and the like; polyethylene; polypropylene; polymethyl methacrylate; polyimide; polyurea; polytetrafluoroethylene; polychlorotrifluoroethylene; polydichlorodifluoroethylene; a copolymer of chlorotrifluoroethylene and dichlorodifluoroethylene; copolymers obtained by copolymerizing a monomer mixture containing tetrafluoroethylene and at least one comonomer; fluorine-containing copolymers each having a cyclic structure in the copolymerization main chain; water-absorbing materials each having a coefficient of water absorption of 1% or more; moisture permeation preventive substances each having a coefficient of water absorption of 0.1% or less; and the like.

There is no particular limitation as to a method for forming the protective layer. For instance, a vacuum deposition method, a sputtering method, a reactive sputtering method, an MBE (molecular beam epitaxial) method, a cluster ion beam method, an ion plating method, a plasma polymerization method (high-frequency excitation ion plating method), a plasma CVD method, a laser CVD method, a thermal CVD method, a gas source CVD method, a coating method, a printing method, or a transfer method may be applied.

11) Sealing

The whole organic electroluminescence element of the present invention may be sealed with a sealing cap.

Furthermore, a moisture absorbent or an inert liquid may be used to seal a space defined between the sealing cap and the light-emitting element. Although the moisture absorbent is not particularly limited, specific examples thereof include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, a molecular sieve, zeolite, magnesium oxide and the like. Although the inert liquid is not particularly limited, specific examples thereof include paraffins; liquid paraffins; fluorine-based solvents such as perfluoroalkanes, perfluoroamines, perfluoroethers and the like; chlorine-based solvents; silicone oils; and the like.

12) Production Method of Element

The respective layers that constitute the element in the present invention can be preferably formed by any method of dry film forming methods such as a vapor deposition method and a sputtering method, and wet film forming methods such as a dipping method, a spin coating method, a dip coating method, a casting method, a die coating method, a roll coating method, a bar coating method and a gravure coating method.

Among these, from the viewpoints of light-emission efficiency and durability, the dry film forming methods are preferable. In the case of the wet film forming methods, a residual coating solvent unfavorably damages the light-emitting layer.

Particularly preferably, a resistance heating vacuum deposition method is used. In the resistance heating vacuum deposition method, since only a substance that can be transpired by heating under a vacuum atmosphere can be efficiently heated, whereby the element is not exposed to a high temperature, the element is advantageously subjected to less damage.

The vacuum deposition method is a method in which, in a vacuumed vessel, a deposition material is heated to vaporize or sublimate to deposit on a surface of an adherend disposed at a slightly distanced position to form a thin film. Depending on the kind of the deposition material and the adherend, resistance heating, an electron beam, high-frequency induction, laser or the like is used to carry out heating. Among these, the one that can form a layer at the lowest temperature is the resistance heating vacuum deposition method. Although it cannot form a layer with a material having a high sublimation temperature, all materials that have a low sublimation temperature can form a layer in a state where the adherent material is hardly thermally affected.

The sealing film material in the present invention is characterized in that it can form a layer by means of the resistance heating vacuum deposition method. A conventional sealing material such as silicon oxide, being high in sublimation temperature, has been impossible to deposit by means of resistance heating. Furthermore, in a vacuum deposition method such as an ion plating method generally described in known examples, since a vaporizing portion becomes such a high temperature as several thousands of degrees centigrade to adversely thermally affect and modify an adherent material, this method is not appropriate as a production method of a sealing film of an organic EL element that is particularly easily affected by heat and UV rays.

13) Driving Method

In the organic electroluminescence element of the present invention, when a DC (AC components may be contained as occasion arises) voltage (usually 2 volts to 15 volts) or DC is applied across the anode and the cathode, luminescence can be obtained.

For the driving method of the organic electroluminescence element of the present invention, the driving methods described in JP-A Nos. 2-148687, 6-301355, 5-29080, 7-134558, 8-234685, and 8-241047; Japanese Patent No. 2784615, U.S. Pat. Nos. 5,828,429 and 6,023,308 are applicable.

### APPLICATION OF THE COLOR DISPLAY OF THE PRESENT INVENTION

The color display of the present invention can be appropriately used in wide fields including displays for mobile phone and personal digital assistants (PDAs), computer displays, car information displays, TV monitors, and general illumination.

All publications, patent applications, and technical standards mentioned in this specification are herein incorporated by reference to the same extent as if each individual publication, patent application, or technical standard was specifically and individually indicated to be incorporated by reference.

### EXAMPLES

### Example 1

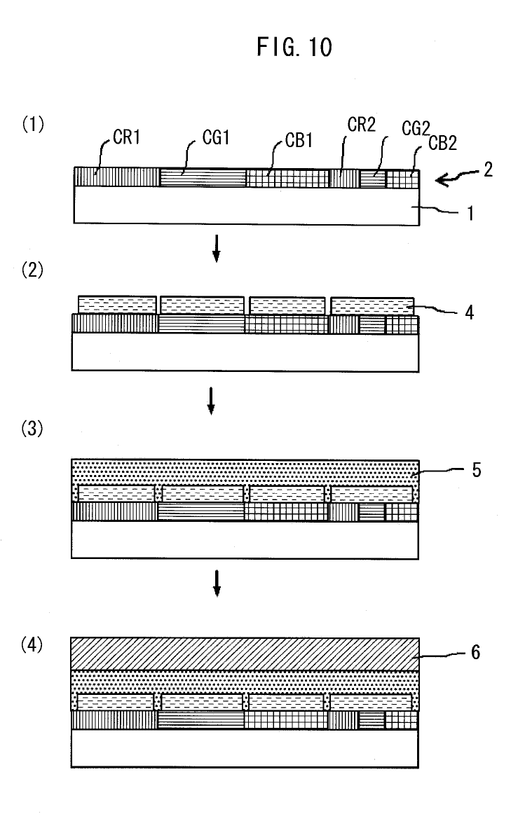

A method for producing the color display of the invention having the structure shown in FIG. 6 is described with reference to the drawings. FIG. 10 shows production processes in accordance with a process order.
(1) A color filter layer (CF layer 2) is formed on a substrate 1. In this process, corresponding to each sub-pixel unit, CR1, CG1, and CB1 are patterned at an R sub-pixel unit, a G sub-pixel unit, and a B sub-pixel unit, respectively, and CR2, CG2, and CB2 are patterned corresponding to each of divided sub-sub-pixel units in the W sub-pixel unit. As a method for patterning, any of a photolithography method using a photosensitive color resist and an ink jet method applying a color resist may be used.
(2) A transparent electrode 4 (formed of ITO, IZO, or the like) is formed electrically separately for each sub-pixel on the upper surface of the CF layer 2. The transparent electrode 4 may be patterned by a film forming method using a shadow mask or a photolithography method after a film is formed on the entire surface.
(3) A white organic electroluminescence layer 5 (white OLED) is formed on the upper surface of the transparent electrode 4. The white OLED has plural organic compound layers containing at least a light-emitting layer, and may be formed by any of a vacuum film forming method and a coating method.
(4) A metal electrode (Al, Ag, or the like) is formed as a light-reflection electrode 6 on the upper surface of the white OLED by a vacuum film forming method.
(5) The OLED formation area is sealed, and each electrode is connected to an external signal control device.
(6) A display surface is formed by disposing plural pixels containing the R, G, B, and W sub-pixels, and then, by selectively emitting each sub-pixel, an image is formed on the display surface.

The light emitted from the W sub-pixel by applying an electric current is different in spectral properties from those of the white OLED itself, and is imparted with spectral properties according to the transmittance of each of the color filters CR2, CG2, and CB2 in the W sub-pixel. In particular, by forming sub-sub-pixels having R, G, and B filters in the W pixel, the outside light is absorbed in the color filter in the W sub-pixel, and a reduction in contrast due to light-reflection on the light-reflection electrode surface is prevented. Thus, even when the image displayed surface is observed under the environment where the outside light enters, a high quality image with a clear black display region can be observed.

### Example 2

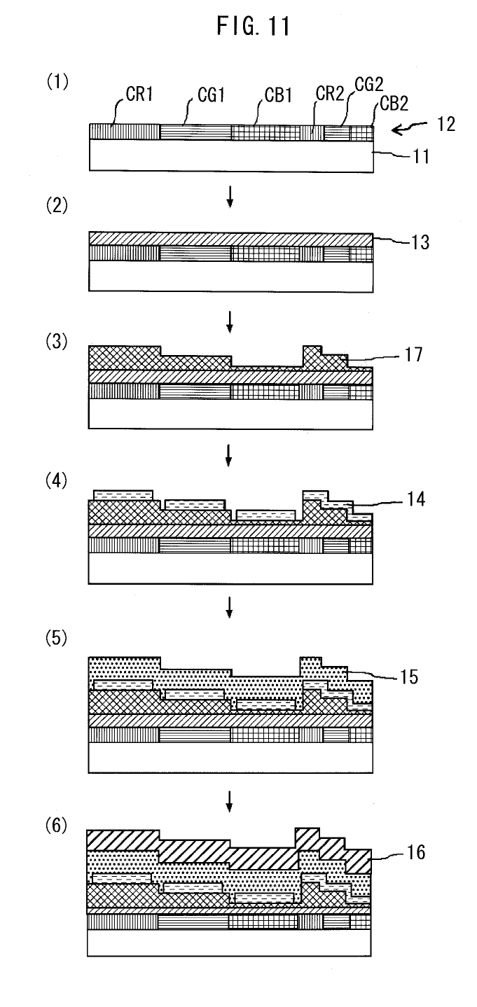

A method for producing a color display of the invention having the structure shown in FIG. 7 is described with reference to the drawings. FIG. 11 shows production processes in accordance with a process order.
(1) The formation of a color filter CF layer 12 on a substrate 11 is conducted in a similar manner to that in the formation of the CF layer 2 in Example 1.
(2) A layer that partially transmits light and partially reflects light 13 is formed on the upper surface of the CF layer 12. The layer that partially transmits light and partially reflects light 13 may be any of metal thin layers (Al, Ag, and the like) and a Distribution Bragg Reflection film (DBR) in which transparent thin layers having a different refractive index are laminated.
(3) An optical path length-adjusting layer 17 whose thickness is different according to R, G, and B is formed according to the patterning of the CF layer 12 on the upper surface of the layer that partially transmits light and partially reflects light. For example, between the layer that partially transmits light and partially reflects light 13 and a light-reflection electrode 16 mentioned later, a film thickness having an optical path length L (L=λ/2*m, λ: Output wavelength, m: natural number) which generates optical resonance in an R light (λ=625 nm to 740 nm), a G light (λ=500 nm to 565 nm), or a B light (λ=450 nm to 485 nm) is achieved. A material of the optical path length-adjusting layer 17 is a transparent insulating material, and may be an inorganic material or an organic material. As the inorganic insulating material, SiO₂, SiON, SiN, and the like are preferably used. As the organic material, polycarbonate, acrylate, silicone, and the like are preferably used.
(4) A transparent electrode 14 (formed of ITO, IZO, or the like) is formed electrically separately for each sub-pixel on the upper surface of the optical path length-adjusting layer 17.
(5) A white organic EL layer 15 is formed substantially in a similar manner to that in the formation process (3) of the white organic EL layer 5 of Example 1.
(6) A light-reflection electrode 16 is formed substantially in a similar manner to that in the formation process (4) of the light-reflection electrode 6 of Example 1.

The light emitted from the W sub-pixel by applying an electric current is different in spectral properties from those of the white OLED itself, and is imparted with spectral properties according to the transmittance of each of the color filters CR2, CG2, and CB2 in the W sub-pixel. As compared with Example 1, by forming an optical resonator structure, the luminescence intensity from each of the R, G, and B sub-pixels is increased, and the brightness thereof increases. In particular, although the brightness decreases by providing the R, G, and B filters in the W sub-pixel, a reduction in brightness is improved by introducing the optical resonator structure in each of the R, G, and B sub-sub-pixels of the W sub-pixel unit. Thus, a high quality image which has a high brightness and in which a reduction in contrast due to outside light-reflection is prevented can be observed.

### Example 3

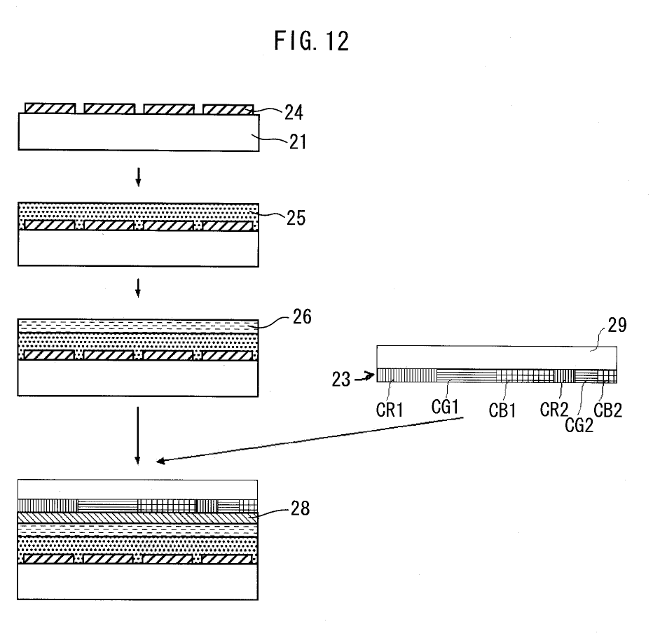

A method for producing a color display of the invention having the structure shown in FIG. 8 is described with reference to the drawings. FIG. 12 shows production processes in accordance with a process order. Examples 1 and 2 are bottom emission types in which an emitted light is taken out from the substrate side. In contrast, Example 3 relates to an embodiment of a top emission type in which the order of disposing the transparent electrode, the white OLED, and the metal electrode is reversed, and light emission is taken out from the upper surface.
(1) On a substrate 21, a light-reflection electrode 24, a white organic electroluminescence layer 25, and a transparent electrode 26 are disposed in this order, thereby preparing an OLED substrate.
(2) Separately, a color filter substrate in which a CF layer 23 is formed on a transparent substrate 29 in a similar manner to that in the formation of the CF layer 2 of process (1) of Example 1 is prepared.
(3) The OLED substrate of process (1) above and the color filter substrate of process (2) above are mutually aligned with respect to pixels, and then the respective substrates are pasted together by an adhesive layer 28 interposed therebetween so that a device-forming surface of each substrate faces with each other.

### Example 4

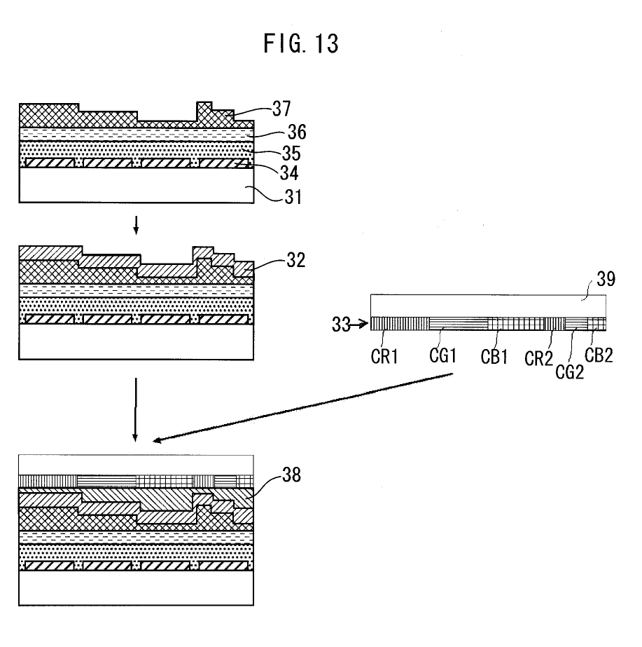

Example 4 relates to an embodiment of a top emission type having a resonator structure in Example 3. FIG. 13 shows production processes in accordance with a process order.
(1) On a substrate 31, a light-reflection electrode 34, a white organic electroluminescence layer 35, a transparent electrode 36, an optical path length-adjusting layer 37 and a layer that partially transmits light and partially reflects light 32 are disposed in this order, thereby preparing an OLED substrate.
(2) Separately, a color filter substrate in which a CF layer 33 is formed on a transparent substrate 39 in a similar manner to that in the formation of the CF layer 2 of process (1) of Example 1 is prepared.
(3) The OLED substrate of process (1) above and the color filter substrate of process (2) above are mutually aligned with respect to pixels, and then the respective substrates are pasted together with an adhesive layer 38 interposed therebetween so that a device forming surface of each substrate faces with each other.

### Example 5

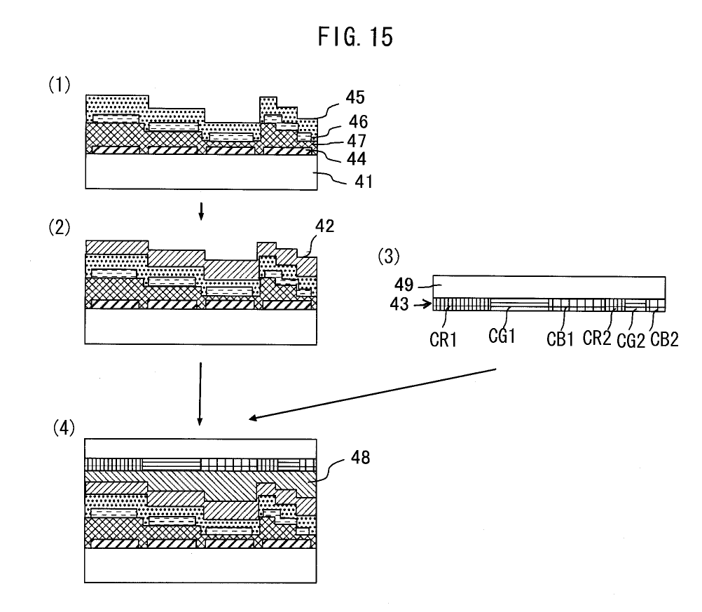

Example 5 relates to a method for production of another embodiment of a top emission type color display having a resonator structure as in Example 4, and is described with reference to the drawings. The color display is illustrated in FIG. 14. FIG. 15 shows production processes in accordance with a process order.
(1) On a substrate 41, a light-reflection layer 44, an optical path length-adjusting layer 47, a transparent electrode 46, a white organic electroluminescence layer 45, and an electrode that partially transmits light and partially reflects light 42 are disposed in this order, thereby preparing an OLED substrate.
(2) Separately, a color filter substrate in which a CF layer 43 is formed on a transparent substrate 49 in a similar manner to that in the formation of the CF layer 2 of process (1) of Example 1 is prepared.
(3) The OLED substrate of process (1) above and the color filter substrate of process (2) above are mutually aligned with respect to pixels, and then the respective substrates are pasted together by an adhesive layer 48 interposed therebetween so that a device-forming surface of each substrate faces with each other.

### Example 6

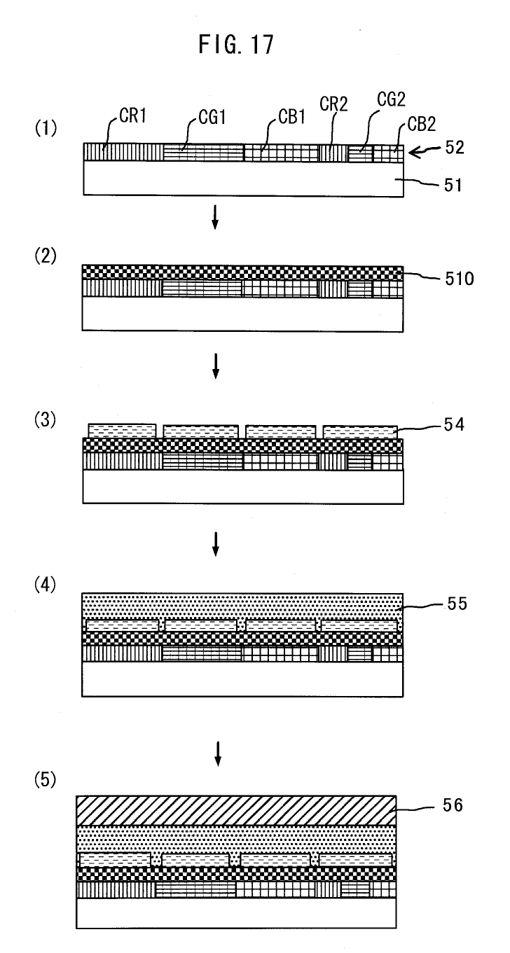

Example 6 relates to an embodiment in which a light extraction structure is provided to Example 1. Example 6 relates to a method for producing a color display having the structure shown in FIG. 16. FIG. 17 shows production processes in accordance with a process order.
(1) On a substrate 51, a CF layer 52 is formed in a similar manner to that in the formation of the CF layer 2 of Example 1.
(2) A light extraction structure layer 510 is formed on the upper surface of the CF layer 52. The light extraction structure layer 510 may be formed by any of the following (A) and (B) processes.
(A) A layer in which fine particles (refractive index 1.8) having a particle size of less than 1 μm are dispersed in a transparent resist (refractive index 1.5) is applied and then cured. A transparent resist used has a composition excluding only a coloring material from the material composition forming the CF layer, and the particles are particles of ITO, SiN, TiO₂, ZnO, or the like.
(B) Pores or projections of having a particle size of less than 1 μm are periodically patterned with a transparent resist (refractive index 1.5). The upper surface thereof is covered with a layer of a light transmission insulating layer SiN (refractive index 1.8), thereby forming a diffraction grating. The transparent resist has a composition excluding only a coloring material from the material composition forming the CF layer, and has photosensitivity. Thus, the periodic patterning is achieved by a photolithography method. Or, a replica method including pressing a master on which pores or projections are periodically arranged for transferring the same may be used.
(3) A transparent electrode 54 is formed electrically separately for each sub-pixel on the upper surface of the light extraction structure layer 510 in a similar manner to that in the formation of the transparent electrode 4 of Example 1.
(4) A white organic electroluminescence layer 55 (white OLED) is formed on the upper surface of the transparent electrode 54 in a similar manner to that in the formation of the white organic electroluminescence layer 5 of Example 1.
(5) A light-reflection electrode 56 is formed on the upper surface of the white OLED in a similar manner to that in the formation of the light-reflection electrode 6 of Example 1.

By providing the light extraction structure layer, a light distribution component of a white OLED which has a total reflection angle of 56° or more relative to the surface normal line generated due to the refractive index difference between the CF layer (refractive index 1.5) and the transparent electrode (refractive index 1.8) can be taken out from an observation side outside the substrate through the CF layer, and the improvement in brightness or power-saving is achieved.

### Example 7

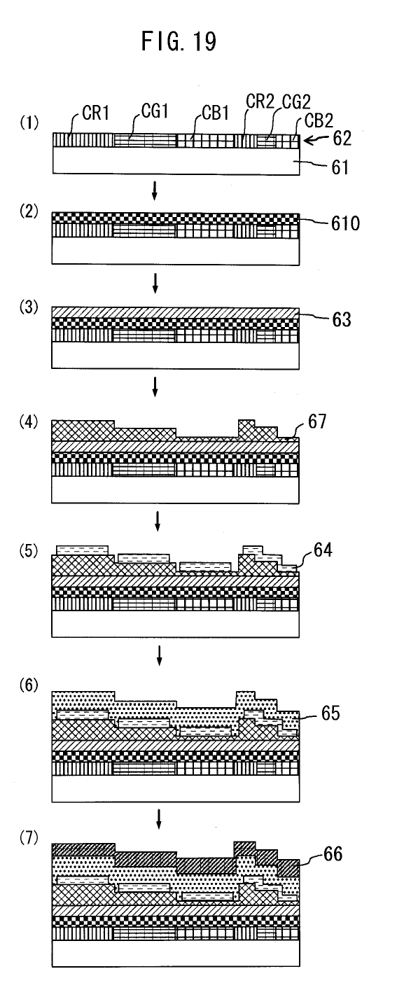

Example 7 relates to an embodiment in which a light extraction structure is provided to Example 2. Example 7 relates to a method for producing a color display having the structure shown in FIG. 18. FIG. 19 shows production processes in accordance with a process order.
(1) On a substrate 61, a CF layer 62 is formed in a similar manner to that in the formation of the CF layer 2 of Example 1.
(2) A light extraction structure layer 610 is formed on the upper surface of the CF layer 62 in a similar manner to that in the formation of the light extraction structure 510 of Example 6. The light extraction structure layer 610 may be formed by any of the following (A) and (B) processes described in Example 6.
(3) A layer that partially transmits light and partially reflects light 63 is formed on the upper surface of the light extraction structure layer 610 in a similar manner to that in the formation of the layer that partially transmits light and partially reflects light 13 of Example 2.
(4) An optical path length-adjusting layer 67 is formed on the upper surface of the layer that partially transmits light and partially reflects light 63 in a similar manner to that in the formation of the optical path length-adjusting layer 17 of Example 2. The thickness of the optical path length-adjusting layer 67 is different from each other according to R, G, and B formed corresponding to the patterning of the CF layer 62.
(5) A transparent electrode 64 is formed electrically separately for each sub-pixel on the upper surface of the optical path length-adjusting layer 67 in a similar manner to that in the formation of the transparent electrode 4 of Example 1.
(6) A white organic electroluminescence layer 65 (white OLED) is formed on the upper surface of the transparent electrode 64 in a similar manner to that in the formation of the white organic electroluminescence layer 5 of Example 1.
(7) A light-reflection electrode 66 is formed on the upper surface of the white OLED in a similar manner to that in the formation of the light-reflection electrode 6 of Example 1.

### Example 8

Example 8 relates to an embodiment in which a light extraction structure is provided to Example 3. Example 8 relates to a method for producing a color display having the structure shown in FIG. 20. FIG. 21 shows production processes in accordance with a process order.
(1) On a substrate 71, a light-reflection electrode 74, a white organic electroluminescence layer 75, and a transparent electrode 76 are disposed in this order, thereby preparing an OLED substrate.
(2) Separately, a color filter substrate in which a CF layer 73 is formed on a transparent substrate 79 in a similar manner to that in the formation of the CF layer 2 of Example 1 is prepared.
(3) A light extraction structure layer 710 is formed on the upper surface of the CF layer 73 in a similar manner to that in the formation of the light extraction structure layer 510 of Example 6. The light extraction structure layer 710 may be formed by any of the following (A) and (B) processes described in Example 6.
(4) The OLED substrate of process (1) above and the color filter substrate of process (3) above are mutually aligned with respect to pixels, and then the respective substrates are pasted together by an adhesive layer 78 interposed therebetween so that a device-forming surface of each substrate faces with each other. The adhesive layer 78 contains a dispersion of fine particles (refractive index 1.8) having a particle size less than 1 μm in a transparent resin adhesive (refractive index 1.5). The fine particles are particles of ITO, SiN, TiO₂, ZnO or the like.

### Example 9

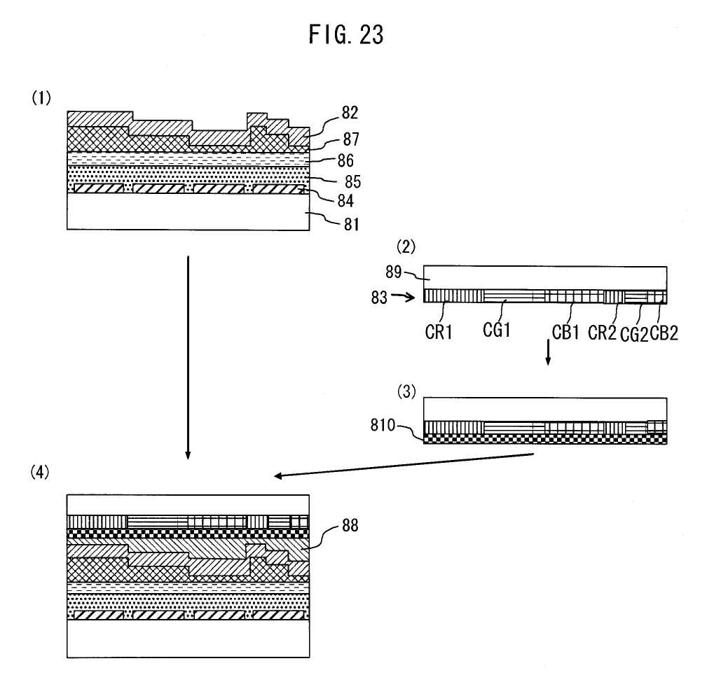

Example 9 relates to an aspect in which a light extraction structure is provided to Example 4. Example 9 relates to a method for producing a color display having the structure shown in FIG. 22. FIG. 23 shows gradual production processes.
(1) On a substrate 81, a light-reflection electrode 84, a white organic electroluminescence layer 85, a transparent electrode 86, an optical path length-adjusting layer 87 and a layer that partially transmits light and partially reflects light 82 are disposed in this order, thereby preparing an OLED substrate.
(2) Separately, a color filter substrate in which a CF layer 83 is formed on a transparent substrate 89 in a similar manner to that in the formation of the CF layer 2 of Example 1 is prepared.
(3) A light extraction structure layer 810 is formed on the upper surface of the CF layer 83 in a similar manner to that in the formation of the light extraction structure layer 510 of Example 6. The light extraction structure layer 810 may be formed by any of the following (A) and (B) processes described in Example 6.
(4) The OLED substrate of process (1) above and the color filter substrate of process (3) above are mutually aligned with respect to pixels, and then the respective substrates are pasted together with an adhesive layer 88 interposed therebetween so that a device-forming surface of each substrate faces with each other. The adhesive layer 88 contains a dispersion of fine particles (refractive index 1.8) having a particle size of less than 1 μm in a transparent resin adhesive (refractive index 1.5). The fine particles are particles of ITO, SiN, TiO₂, ZnO or the like.

### Example 10

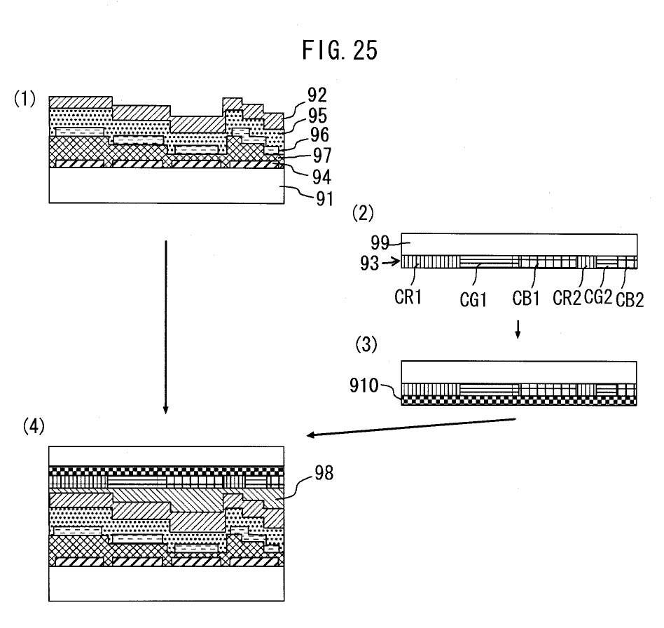

Example 10 relates to an embodiment in which a light extraction structure is provided to Example 5. Example 10 relates to a method for producing a color display having the structure shown in FIG. 24. FIG. 25 shows production processes in accordance with a process order.
(1) On a substrate 91, a light reflection layer 94, an optical path length-adjusting layer 97, a transparent electrode 96, a white organic electroluminescence layer 95, and an electrode that partially transmits light and partially reflects light 92 are disposed in this order, thereby preparing an OLED substrate.
(2) Separately, a color filter substrate in which a CF layer 93 is formed on a transparent substrate 99 in a similar manner to that in the formation of the CF layer 2 of Example 1 is prepared.
(3) A light extraction structure layer 910 is formed on the upper surface of the CF layer 93 in a similar manner to that in the formation of the light extraction structure layer 510 of Example 6. The light extraction structure layer 910 may be formed by any of the following (A) and (B) processes described in Example 6.
(4) The OLED substrate of process (1) above and the color filter substrate of process (3) above are mutually aligned with respect to pixels, and then the respective substrates are pasted together with an adhesive layer 98 interposed therebetween so that a device forming surface of each substrate faces with each other. The adhesive layer 98 contains a dispersion of fine particles (refractive index 1.8) having a particle size of less than 1 μm in a transparent resin adhesive (refractive index 1.5). The fine particles are particles of ITO, SiN, TiO₂, ZnO or the like.

Reference numerals used in Figures of the invention are explained below.
1, 11, 21, 31, 41, 51, 61, 71, 81, 91: Substrate
2, 12, 23, 33, 43, 52, 62, 73, 83, 93: Color filter layer (CF layer)
4, 14, 26, 36, 46, 54, 64, 76, 86, 96: Transparent electrode
5, 15, 25, 35, 45, 55, 65, 75, 85, 95: White organic electroluminescence layer
6, 16, 24, 34, 56, 66, 74, 84: Light-reflection electrode
44, 94: Light reflection layer
28, 38, 48, 78, 88, 98: Adhesive layer
29, 39, 49, 79, 89, 99: Transparent substrate
13, 32, 63, 82: Layer that partially transmits light and partially reflects light
42, 92: Electrode that partially transmits light and partially reflects light
510, 610, 710, 810, 910: Light extraction structure layer
17, 37, 47, 67, 87, 97: Optical path length-adjusting layer

What is claimed is:

1. A color display using an organic electroluminescence element, comprising, on a substrate, plural pixels each being area-divided into plural sub-pixels including at least two sub-pixels that each emit colored light of different wavelengths and a white sub-pixel, in which the white sub-pixel is further area-divided into at least two sub-sub-pixels that each emit colored light of different wavelengths, wherein the at least two sub-pixels and the at least two sub-sub-pixels each have an organic electroluminescence layer that emits a white light and a color filter.

2. The color display according to claim 1, wherein the at least two sub-pixels include at least three sub-pixels including a blue sub-pixel, a green sub-pixel and a red sub-pixel, each having a blue filter, a green filter and a red filter, respectively, for each same color, and the white sub-pixel includes a blue sub-sub-pixel, a green sub-sub-pixel and a red sub-sub-pixel, each having a blue filter, a green filter and a red filter, respectively, for each same color.

3. The color display according to claim 2, wherein the blue filter, the green filter and the red filter of the respective blue sub-pixel, green sub-pixel and red sub-pixel, and the blue filter, the green filter and the red filter of the respective blue sub-sub-pixel, green sub-sub-pixel and red sub-sub-pixel have substantially the same composition, respectively, for each same color.

4. The color display according to claim 1, wherein each of the at least two sub-sub-pixels of the white sub-pixel forms a resonator.

5. The color display according to claim 1, wherein each of the at least two sub-pixels forms a resonator.

6. The color display according to claim 2, wherein each of the blue sub-pixel, the green sub-pixel and the red sub-pixel forms a resonator, and each of the blue sub-sub-pixel, the green sub-sub-pixel and the red sub-sub-pixel forms a resonator, in which the resonators of the blue sub-pixel and the blue sub-sub-pixel, the resonators of the green sub-pixel and the green sub-sub-pixel, and the resonators of the red sub-pixel and the red sub-sub-pixel have substantially the same structure, respectively, for each same color.

7. A method for producing a color display using an organic electroluminescence element, comprising, on a substrate, plural pixels each being area-divided into plural sub-pixels including at least two sub-pixels that each emit colored light of different wavelengths and a white sub-pixel, in which the white sub-pixel is further area-divided into at least two sub-sub-pixels that each emit colored light of different wavelengths, wherein the at least two sub-pixels and the at least two sub-sub-pixels each have an organic electroluminescence layer that emits a white light and a color filter, the method comprising:
forming the color filters for the at least two sub-pixels and the at least two sub-sub-pixels in succession with substantially the same composition for each same color; and
forming the organic electroluminescence layers that emit a white light for the at least two sub-pixels and the at least two sub-sub-pixels in succession with substantially the same composition.

8. The method for producing a color display according to claim 7, wherein the at least two sub-pixels include at least three sub-pixels including a red sub-pixel, a green sub-pixel, and a blue sub-pixel, and the white sub-pixel includes a red sub-sub-pixel, a green sub-sub-pixel, and a blue sub-sub-pixel.

9. The method for producing a color display according to claim 8, wherein: the red sub-pixel, the green sub-pixel and the blue sub-pixel, and the red sub-sub-pixel, the green sub-sub-pixel and the blue sub-sub-pixel form resonators, respectively, for each same color, and
optical path length-adjusting layers of the red sub-pixel and the red sub-sub-pixel, optical path length-adjusting layers of the green sub-pixel and the green sub-sub-pixel, and optical path length-adjusting layers of the blue sub-pixel and the blue sub-sub-pixel are formed to have substantially the same thickness using the same material for each same color.

10. The method for producing a color display according to claim 9, wherein the optical path length-adjusting layers are formed of an inorganic insulating material.
